(19) United States
(12) Patent Application Publication
(10) Pub. No.: US 2023/0349024 A1
(43) Pub. Date: Nov. 2, 2023

(54) PROCESS MEASUREMENT AND CONTROL AND MATERIAL CHARACTERIZATION IN A REMELTING FURNACE

(71) Applicant: KW Associates LLC, Albany, OR (US)

(72) Inventors: Matthew A. Cibula, Salem, OR (US); Joshua R. Motley, McMinnville, OR (US); Nathan L. Pettinger, Corvallis, OR (US); Daniel R. McCulley, Albany, OR (US); Paul E. King, Albany, OR (US)

(21) Appl. No.: 18/129,816

(22) Filed: Mar. 31, 2023

Related U.S. Application Data
(60) Provisional application No. 63/326,799, filed on Apr. 1, 2022.
(60) Provisional application No. 63/409,203, filed on Sep. 22, 2022.

(51) Int. Cl. C22B 9/20; G01R 31/12

(52) U.S. Cl. CPC C22B 9/20; G01R 31/1227

(57) ABSTRACT

Magnetic field components measured around and along a remelting furnace and other measured furnace parameters are used to estimate concentricity of the electrode within the crucible of the furnace, to estimate a distribution of drip shorts across a gap between the electrode and the melt pool, or to detect, locate, and categorize anomalous events during the remelting process. Those can be used to control the operation of the furnace during the remelting process, or incorporated into a longitudinal or three-dimensional map of the resulting ingot. Artificial intelligence, machine learning, or a neural network can be employed.

### BENEFIT CLAIMS TO RELATED APPLICATIONS

This application claims benefit of (i) U.S. provisional App. No. 63/326,799 entitled “Process measurement and control and material characterization in a remelting furnace” filed 1 Apr. 2022 in the names of Cibula et al, and (ii) U.S. provisional App. No. 63/409,203 entitled “Characterization of vacuum arc remelting with a high-density magnetic field sensor array” filed 22 Sep. 2022 in the names of Cibula et al; both of said applications are incorporated herein by reference in their entireties.

### FIELD OF THE INVENTION

The field of the present invention relates to remelting furnaces. In particular, apparatus and methods are described herein for process measurement and control and material characterization in a remelting furnace.

### BRIEF DESCRIPTION OF THE DRAWINGS

FIG. 1 is a schematic perspective view of an example arrangement of magnetic sensors coupled to a computer system.

FIGS. 2 and 3 are schematic longitudinal cross sections of an example arrangement of a remelting furnace with magnetic sensors.

FIGS. 4A, 4B, and 4C are schematic isometric, top, and side views of an example arrangement of magnetic sensors and sources coupled to a computer system.

FIG. 5 is a schematic longitudinal cross section of an example arrangement of a remelting furnace with magnetic sensors and sources.

FIG. 6 a schematic side view of an example arrangement of magnetic sensors and sources.

FIGS. 7A and 7B are schematic side views of an example arrangement of stationary magnetic sensors and movable magnetic sources.

FIGS. 8A and 8B are schematic side views of an example arrangement of movable magnetic sensors and sources.

FIG. 9 is a schematic side view of an example arrangement of magnetic sensors and sources.

FIG. 10 is a schematic side view of an example arrangement of movable magnetic sensors.

FIGS. 11A and 11B are schematic longitudinal cross sections of an example arrangement of a remelting furnace with movable magnetic sensors earlier (FIG. 11A) and later (FIG. 11B) during a remelting process.

FIGS. 12A and 12B are schematic longitudinal cross sections of an example arrangement of a remelting furnace with movable magnetic sensors earlier (FIG. 12A) and later (FIG. 12B) during a remelting process.

FIGS. 13A and 13B are schematic longitudinal cross sections of an example arrangement of a remelting furnace with stationary and movable magnetic sensors earlier (FIG. 13A) and later (FIG. 13B) during a remelting process.

FIGS. 14A and 14B are schematic longitudinal cross sections of an example arrangement of a remelting furnace with movable magnetic sensors and sources earlier (FIG. 14A) and later (FIG. 14B) during a remelting process.

FIGS. 15A and 15B are schematic longitudinal cross sections of an example arrangement of a remelting furnace with an actuator and movable magnetic sensors earlier (FIG. 15A) and later (FIG. 15B) during a remelting process.

FIGS. 16A and 16B are schematic longitudinal cross sections of an example arrangement of a remelting furnace with an actuator and movable magnetic sensors and sources earlier (FIG. 16A) and later (FIG. 16B) during a remelting process.

FIGS. 17A and 17B are schematic longitudinal cross sections of an example arrangement of a remelting furnace with actuators and movable magnetic sensors earlier (FIG. 17A) and later (FIG. 17B) during a remelting process.

FIGS. 18A and 18B are schematic longitudinal cross sections of an example arrangement of a remelting furnace with actuators and movable magnetic sensors and sources earlier (FIG. 18A) and later (FIG. 18B) during a remelting process.

FIG. 19 includes plots of simulated longitudinal magnetic field components as a function of longitudinal position along a furnace calculated using different transverse positions of an electrode within the furnace and a current segment within the gap.

FIG. 20 includes plots of measured magnetic field components as a function of transverse position of an electrode within the furnace.

FIG. 21 includes plots of measured current, voltage, and magnetic field components during transverse movement of an electrode within a furnace.

FIG. 22 shows measured drip short distributions for two different remelting processes.

The embodiments depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. The embodiments shown are only examples and should not be construed as limiting the scope of the present disclosure or any appended of subsequently presented claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the invention. The detailed description illustrates by way of example, not by way of limitation, the principles of the invention.

Subject matter disclosed herein may be related to subject matter disclosed in one or more of: (i) U.S. Pat. No. 8,111,059; (ii) U.S. Pat. No. 10,514,413; (iii) U.S. Pat. No. 10,761,116; (iv) U.S. Pat. No. 11,022,656; (v) U.S. Pat. No. 11,236,404; (vi) U.S. Pat. No. 11,243,273; (vii) U.S. Pat. No. 11,459,627; or (viii) U.S. Pat. Pub. No. 2022/0154300, all of which are incorporated herein by reference in their entireties.

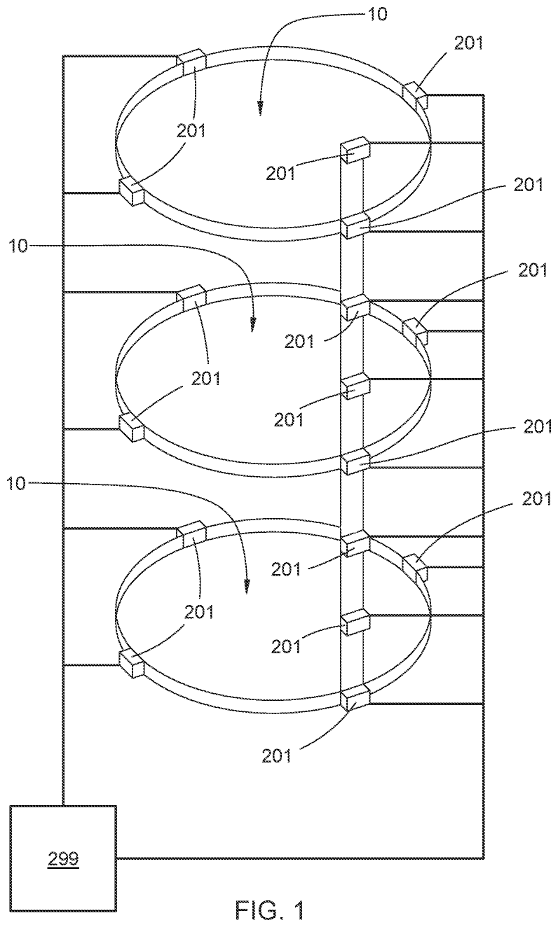

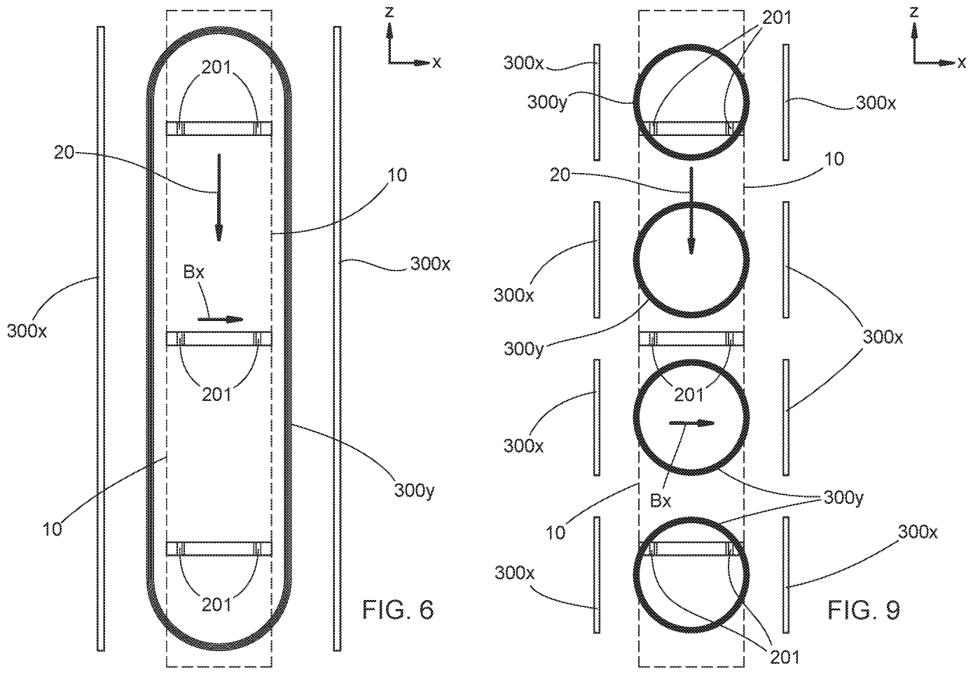

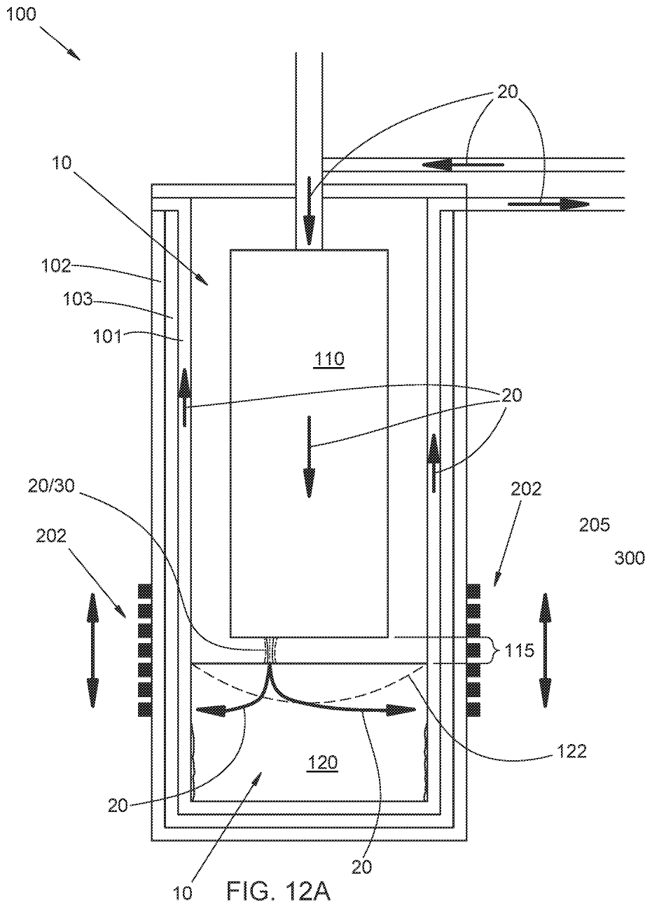

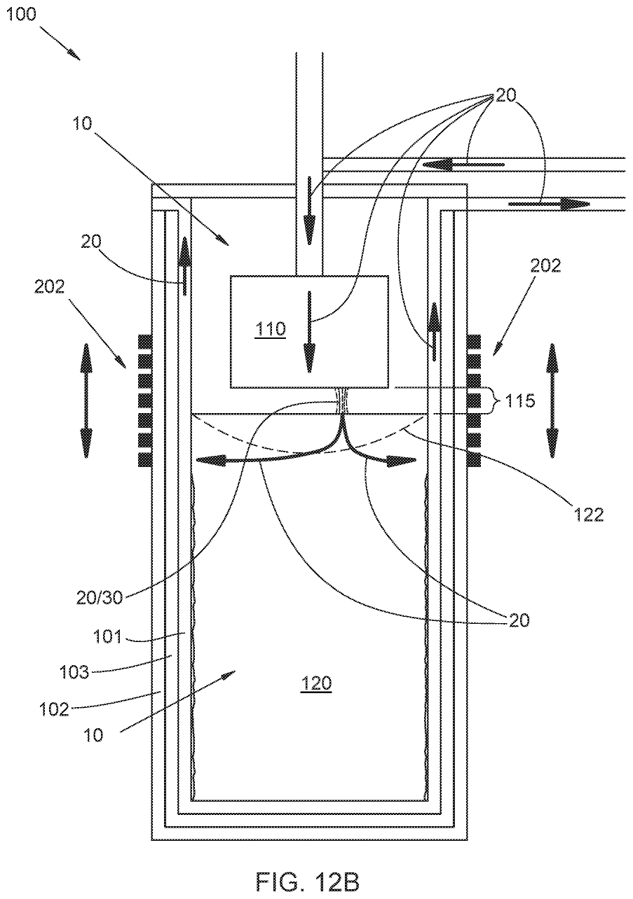

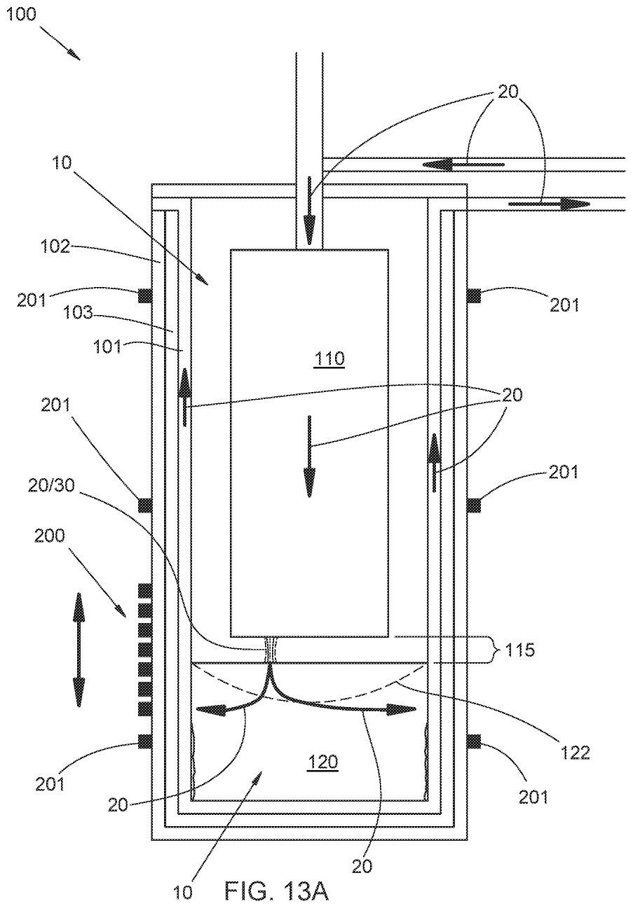

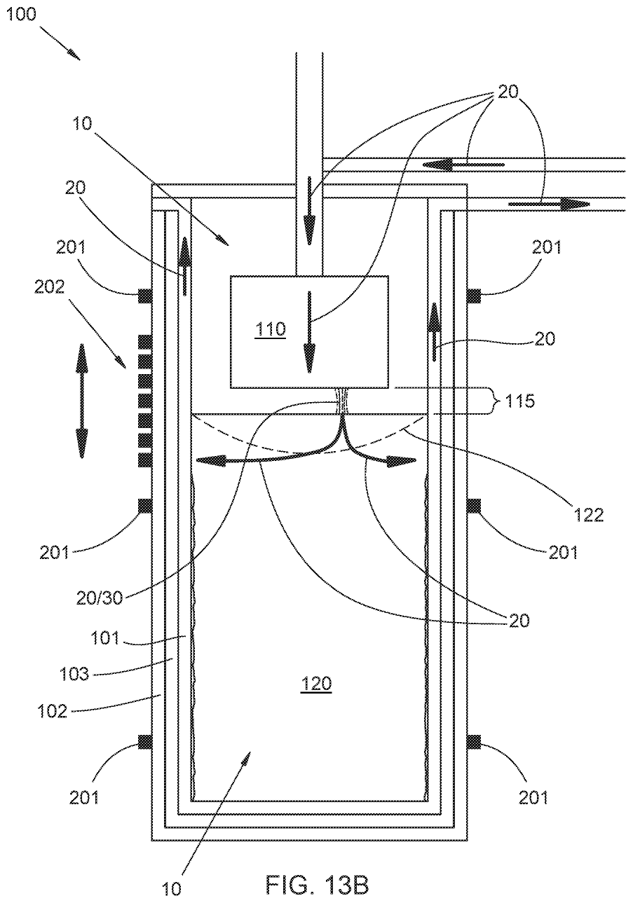

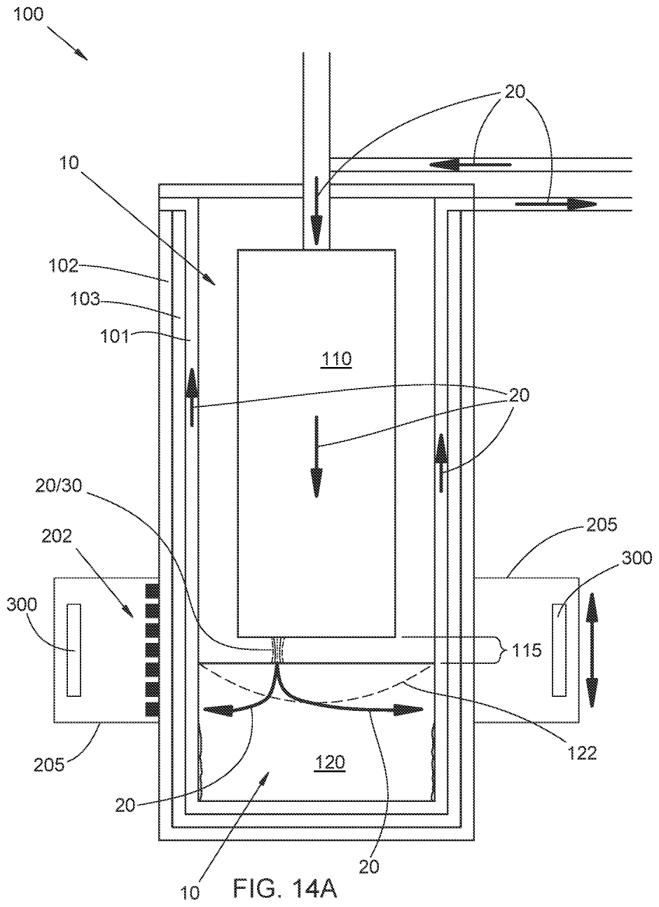

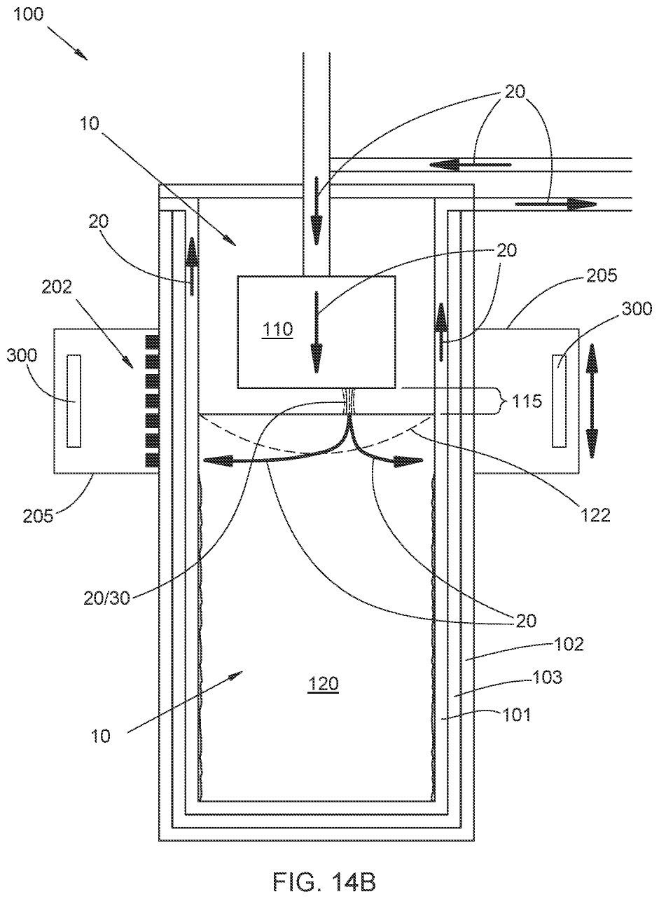

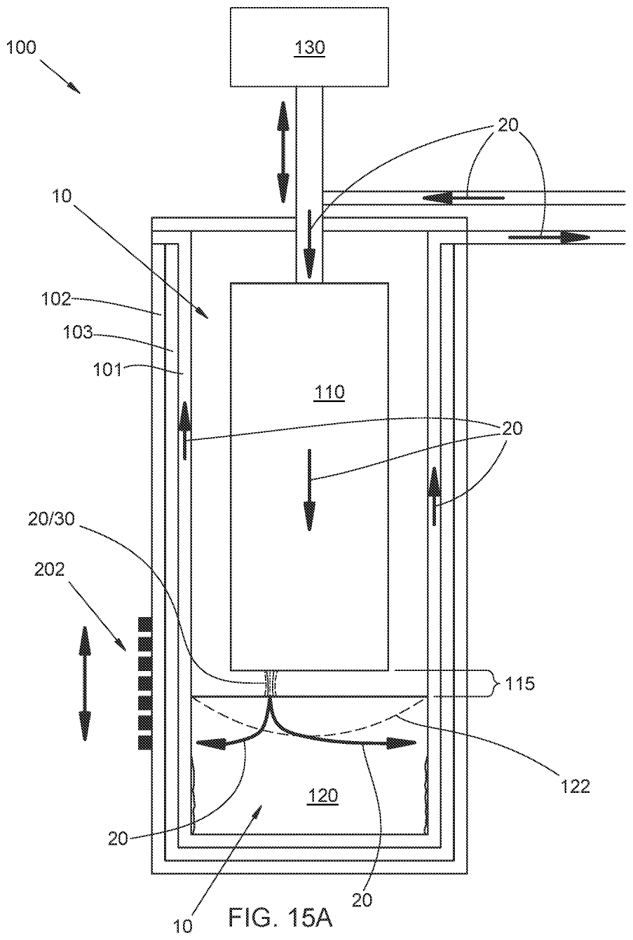

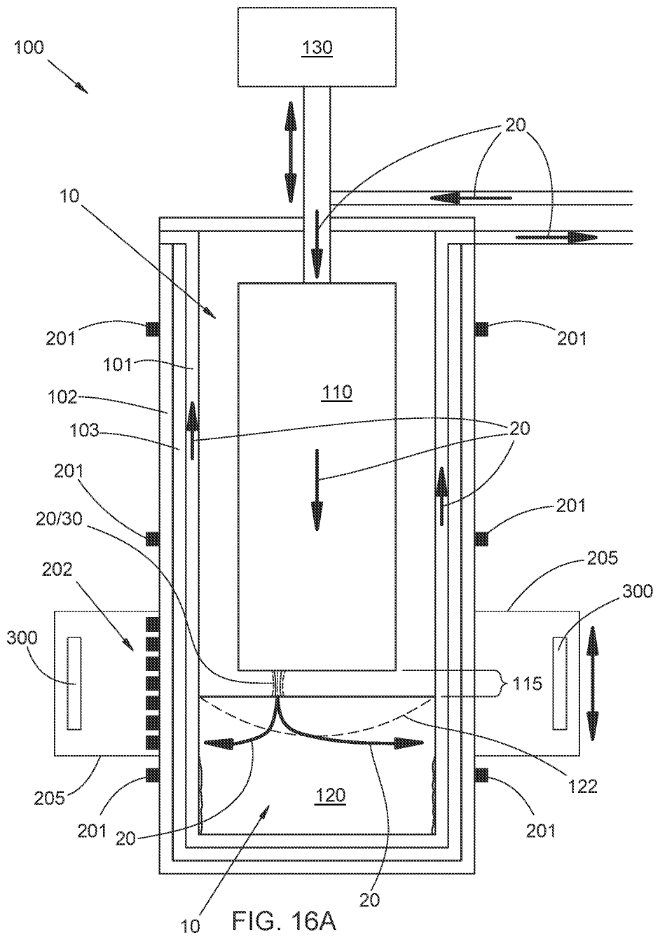

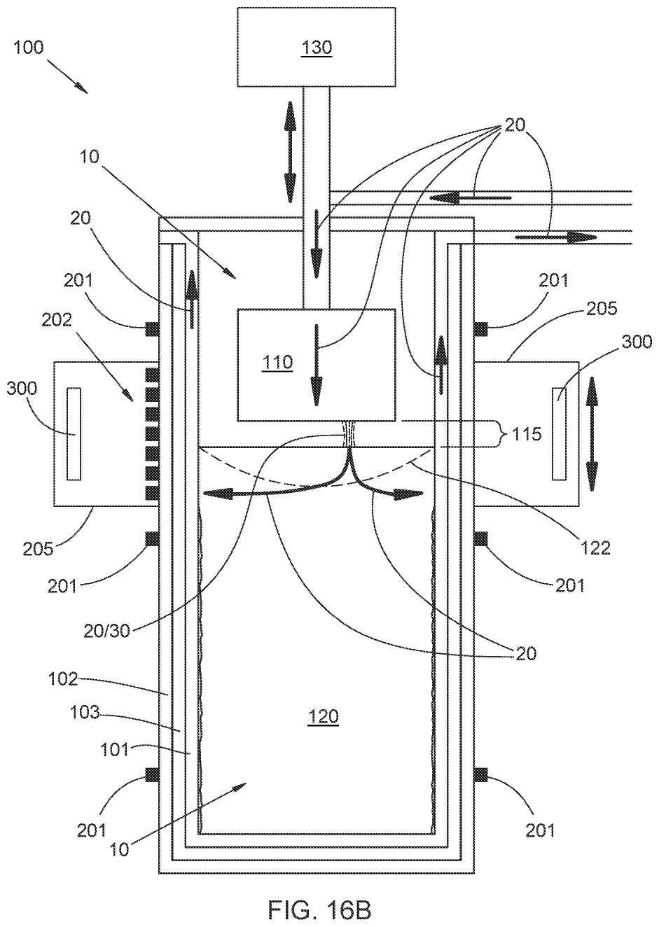

The references cited above disclose apparatus and methods for estimation and/or control of the position and/or length of an electric discharge or arc, or other transversely localized electric current segment 30, that flows longitudinally across a gap 115 between two electrically conductive bodies 110 and 120 (as in the various examples illustrated schematically in FIGS. 1 through 17B). Multiple magnetic field sensors 201 (stationary) and/or 202 (movable) are employed to measure magnetic field components arising from the current segment 30; a computer system 299 is used to calculate an estimated position based on those measured field components and the corresponding locations at which they were measured. Magnetic field sources 300 can be employed to cause transverse movement of the current segment 30, and the field sources 300 and field sensors 201/202 can be coupled in a feedback arrangement or as a servomechanism to apply control fields based on the estimated location of the current segment 30. A longitudinal mechanical actuator 130 of any suitable type or arrangement (e.g., hydraulic, gear-driven, servo-motor, and so forth) can be employed to control the distance between the conductive bodies 110 and 120 and hence the length of the current segment 30, and the longitudinal actuator 130 and field sensors 201/202 can be coupled in a feedback arrangement or as a servomechanism to move one or both conductive bodies 110/120 based on the estimated length of the current segment 30.

Such apparatus and methods can be usefully employed in a variety of settings. One important setting is in the field of remelting furnaces 100, in which an electric current flows through a conductive metal electrode 110 to be melted, through an ingot 120 formed from molten metal from the electrode 110 dripping into a melt pool 122 on the top surface of the ingot 120, and through one or more localized electric current segments 30 spanning the gap 115 between the electrode 110 and the ingot 120. In some furnaces 100 (e.g., vacuum arc remelting furnaces, also referred to as VAR furnaces), the current segment 30 is an electric discharge or arc, and the gap 115 is vacuum, or at most a diffuse plasma generated by the discharge or arc. In other furnaces 100 a gaseous medium occupies the gap 115 between the electrode 110 and the ingot 120. In still other furnaces 100 (e.g., eletroslag remelting furnaces, also referred to as ESR furnaces), molten slag (not shown) occupies the gap 115 between the electrode 110 and the ingot 120. In any of those examples, localized current segments 30 can also include transient short circuits through droplets of molten metal dripping across the gap 115 between the melting electrode 110 and the growing ingot 120 (referred to as drip shorts). Positions or distribution of localized current segments 30 of any or all types, as well as other measured or observed behaviors or parameters during a remelting process, can be strongly correlated with the quality of the metal in the ingot 120 produced by that remelting process. Accordingly, methods and apparatus disclosed herein and in the incorporated references can be advantageously employed for, e.g., altering, maintaining, or otherwise controlling a remelting process, evaluating the quality of metal in the ingot 120 produced by a remelting process, guiding subsequent use, handling or processing of the metal of the ingot 120, or for other purposes.

A general arrangement of stationary magnetic field sensors 201 is shown in FIG. 1. The sensors 201 are arranged around a periphery of a current-containing volume 10 (e.g., the interior volume of a remelting furnace 100) through which an electric current flows in a generally longitudinal direction. The sensors 201 measure magnetic field components, in two transverse dimensions in some examples or (more typically) in all three spatial dimensions in other examples. The sensors 201 are located at corresponding sensor positions at multiple different longitudinal positions along the volume 10 and/or at multiple different circumferential positions around the volume 10. In the example of FIG. 1 the sensors 201 are arranged as three rings of sensors 201 at three different longitudinal positions along the volume 10, as well as additional sensors 201 at other longitudinal positions; other suitable sensor arrangements can be employed. The sensors 201 are coupled to a computer system 299, which receives electronic signals from the sensors 201 indicative of the measured field components. Based on one or some or all of the measured field components, the corresponding positions of the sensors 201, and corresponding calibration factors for the sensors 201, the computer system 299 can calculate an estimated transverse position or distribution of the current flowing through volume 10. That distribution can take the form of one or more localized current segments 30 (e.g., electric discharges or drip shorts in a VAR furnace) within the gap 115, or less localized current distributions within the electrode 110 and the ingot 120. The computer system 299 also can calculate an estimated longitudinal position of one or more localized current segments 30 within the volume 10; those correspond to a longitudinal location within the volume 10 of the gap 115 between the electrode 110 and the ingot 120 (which moves upward through the crucible 101 during the remelting process. Those calculations can be performed in any suitable way (e.g., analytical, numerical, approximated, etc) based on Maxwell's equations or any suitable subset or adaptation thereof (e.g., the Biot-Savart law or Jefimenko's equations). Note that “one or more measured magnetic field components”, “two or more measured magnetic field components, “multiple measured magnetic field components”, “some of the measured magnetic field components”, “all of the measured magnetic field components”, and so forth, can refer to components in multiple different directions all measured at a single corresponding sensor position, components all in a single direction measured at multiple corresponding sensor positions, or components in multiple different directions measured at multiple different corresponding sensor positions.

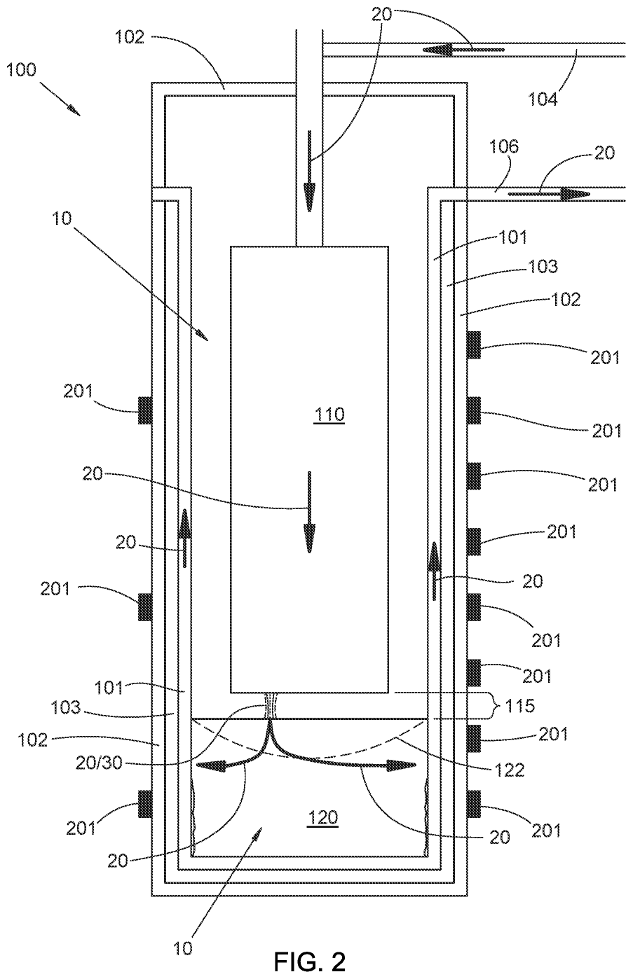

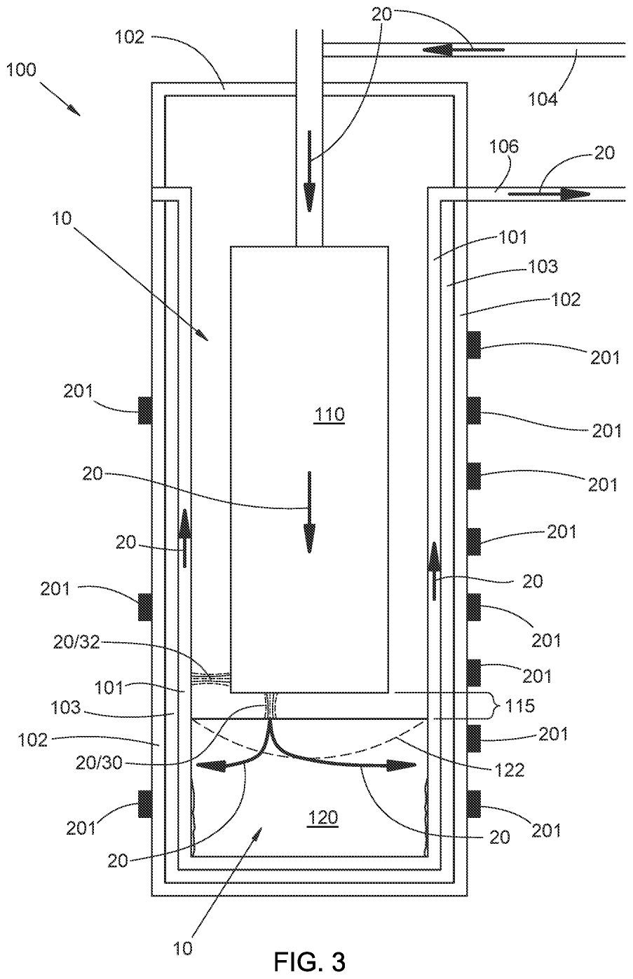

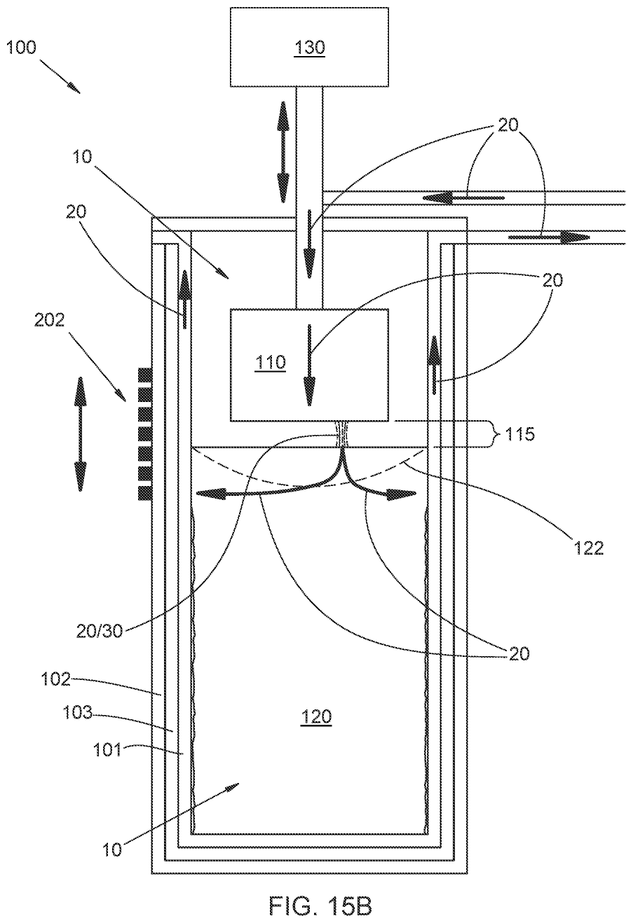

FIGS. 2 and 3 illustrate schematically an example of a remelting furnace 100 that includes a crucible 101, an outer wall 102, and a water-cooled cooling jacket 103 between them. The sensors 201 are arranged about the furnace 100 outside the outer wall 102. A metal electrode 110 in an upper portion of the furnace 100 and a metal ingot 120 in the crucible 101 in a lower part of the furnace are separated by a gap 115. Electric current 20 flows through the electrode 110, across the gap 115 (e.g., as an arc or discharge 30 in a VAR furnace, or other localized current segment(s) 30), through the ingot 120, and through the crucible 101 and the top of the furnace 100; alternatively, in these and subsequent examples the current can instead flow through the crucible 101 at the bottom of the furnace 100. In some instances a portion of the current might flow directly between the electrode 110 and the crucible 101 as a so-called side arc 32 (e.g., as in FIG. 3); side arcs are undesirable, as they can lead to damage to the furnace 100 or introduce impurities or contaminants into the ingot 120. Heat generated by the current 20 at the gap 115 during the remelting process causes the electrode 110 to melt and shrink and the ingot 120 to grow, as molten metal drips from the electrode 110 into the melt pool 122 at the top of the ingot 120. The gap 115 moves upward through the furnace 100 during the remelting process as the ingot 120 grows. Because the electrode 100 has a diameter smaller than that of the ingot 120, the electrode 110 is lowered into the furnace 100 during the remelting process to maintain a relatively constant distance across the gap 115. A longitudinal actuator for that purpose is present in all examples but shown explicitly (as actuator 130) only in FIGS. 15A-18B and is discussed further below.

In some instances the estimated position of the current segment 30 can be recorded as a function of longitudinal position of the gap 115, which corresponds to longitudinal position along the solidified ingot 120 produced by the remelting process. In some examples the measured magnetic field components can be indicative of the presence, and perhaps also transverse location (e.g., position along the circumference of the furnace), of a side arc 32. That side arc information can be recorded as a function of longitudinal position of the gap 115 within the furnace 100, i.e., longitudinal position along the ingot 120, and in some instances also as a function of circumferential position around the furnace 100, i.e., circumferential position around the ingot 120.

Instead of, or in addition to, passively recording arc position or side arc occurrence as a function of longitudinal position along the ingot 120, active measures can be taken during the remelting process in response to the measured field components. In some examples, detection of a side arc 32, or persistence of a side arc 32 longer than a selected time limit, or occurrence of multiple side arcs 32 above a selected threshold number or within a selected time window, can cause the computer system 299 to, e.g., alter or interrupt the current 20, alter the voltage, or move or withdraw the electrode 110. In some instances an interruption or alteration can be temporary and afterward the remelting process can continue as before; in some instances an alteration can persist while the remelting process can continue; in some instances the remelting process might be aborted altogether.

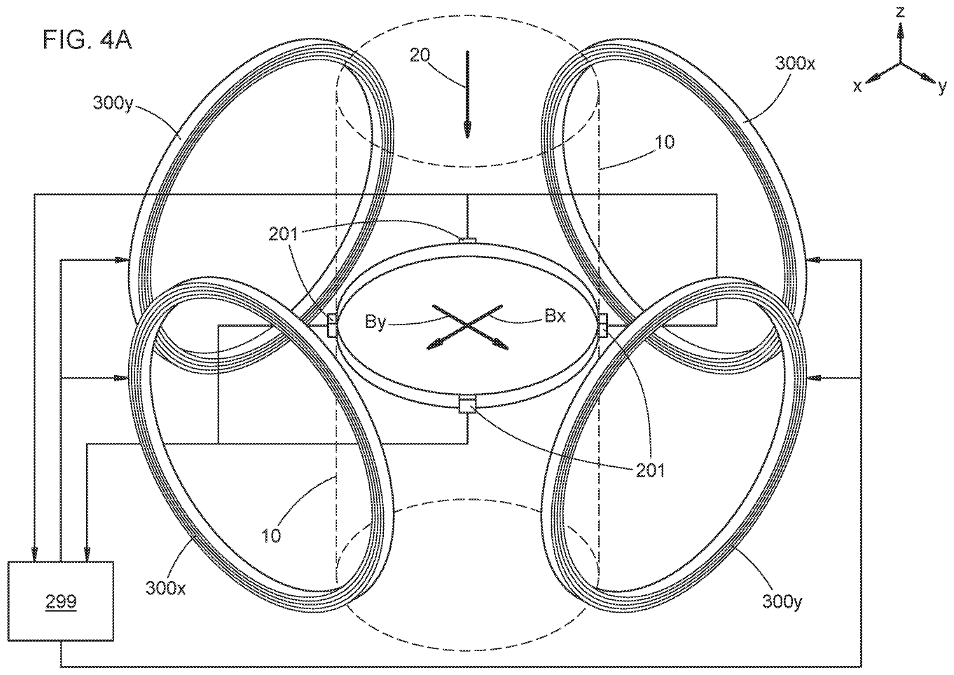

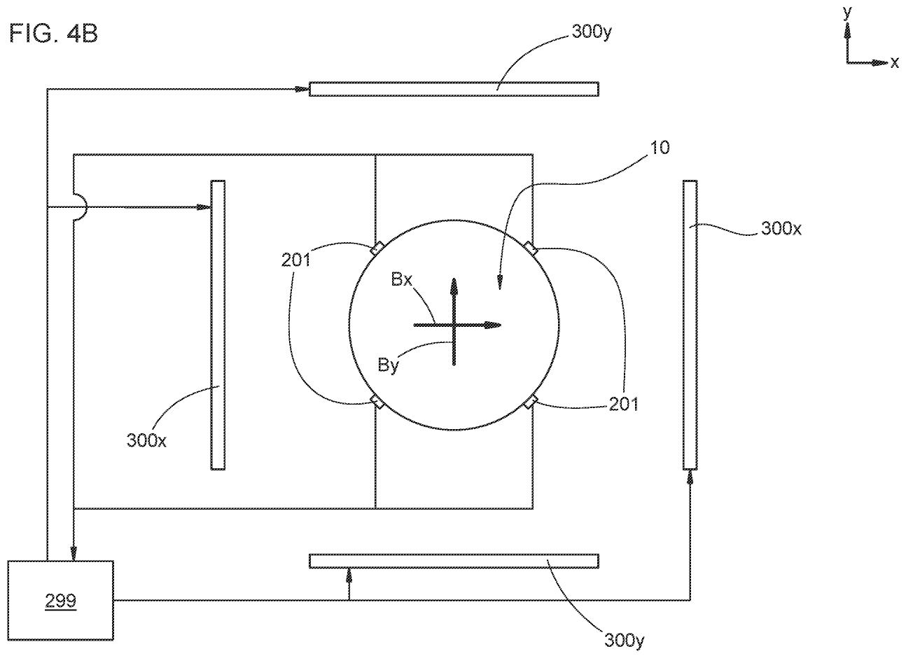

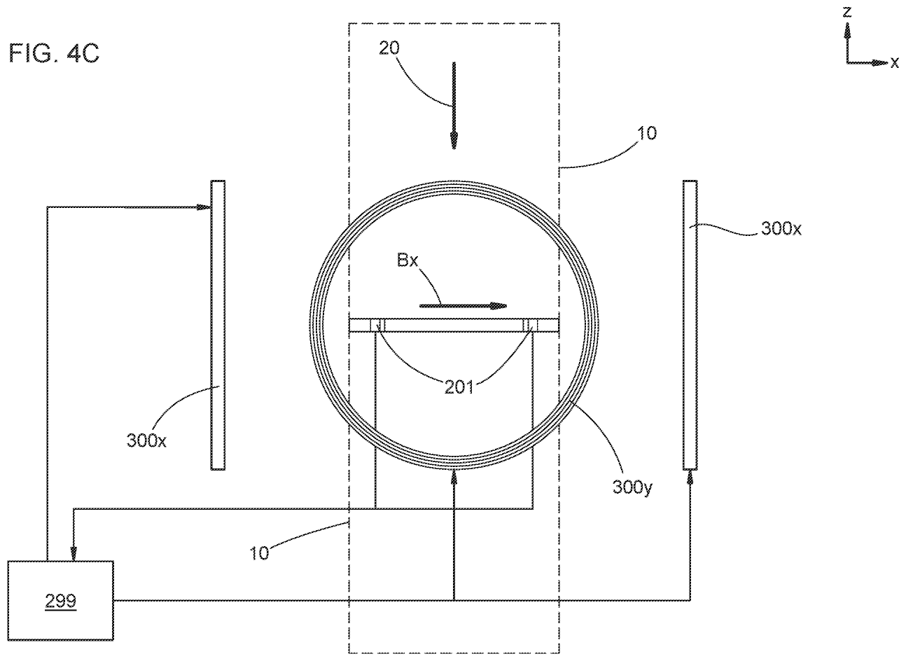

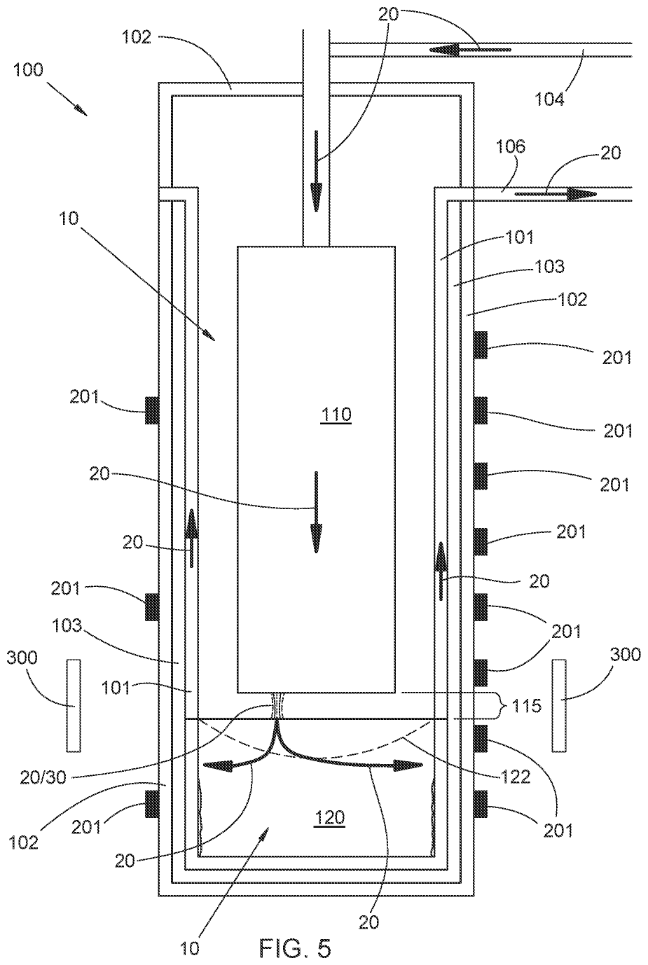

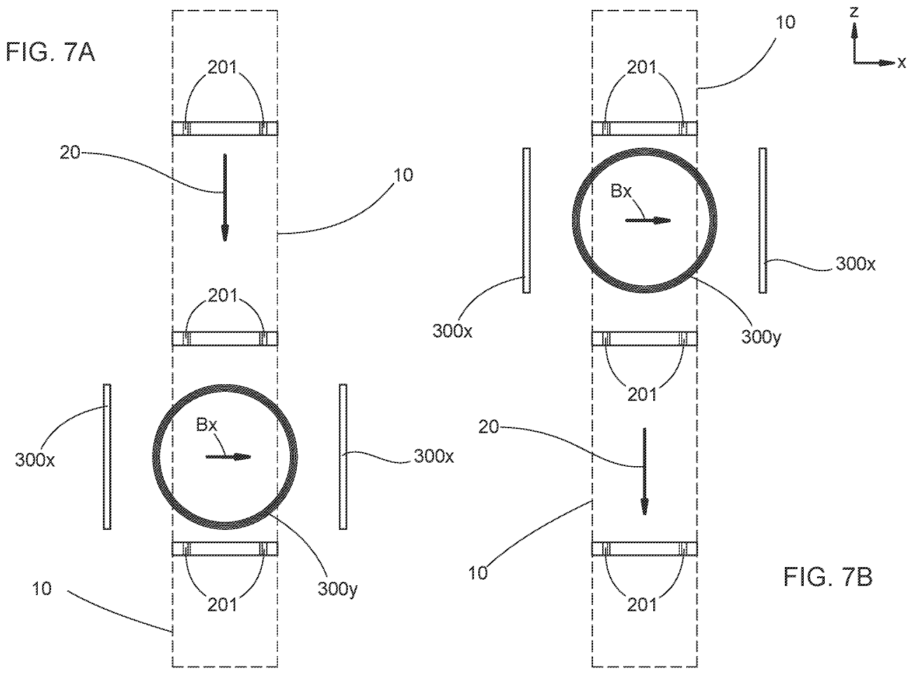

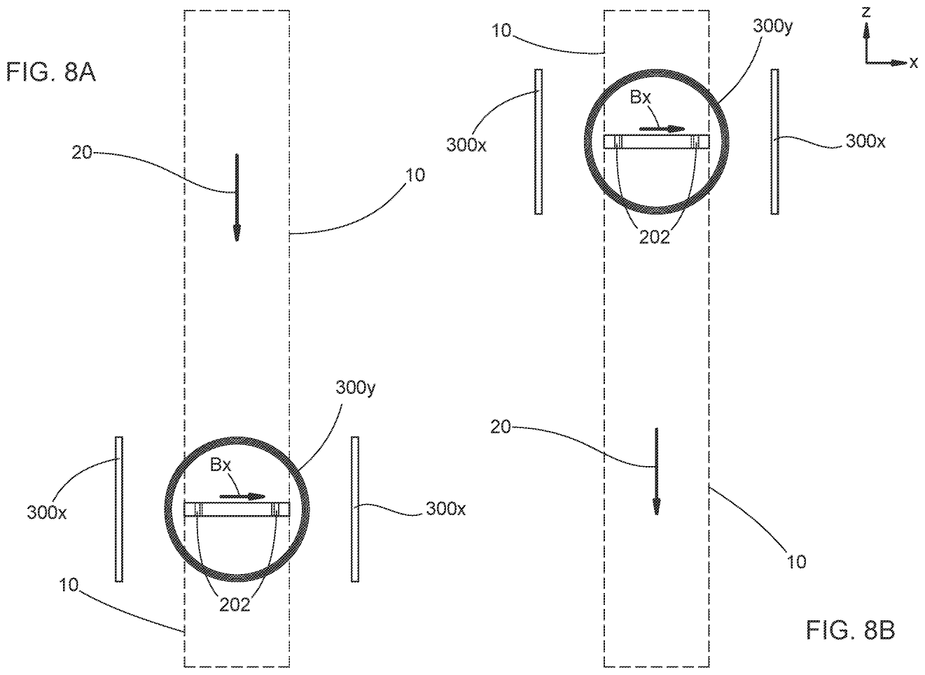

In some examples, magnetic field sources 300 can be positioned around the arc furnace 100 and arranged to enable alteration, maintenance, or control of the transverse position of the current segment 30 within the gap 115. A general arrangement of sources 300 and sensors 201 is illustrated schematically in FIGS. 4A-4C, in which a pair of electrically conductive coils 300x is arranged to apply a magnetic field along the x-direction, and a second pair of coils 300y is arranged to apply a magnetic field along the y-direction. Both sources 300 (i.e., coils 300x/300y) and sensors 201 are operatively coupled to the computer system 299. The computer system 299 can be structured and programmed to cause current to flow through the coils 300x and/or 300y in response to magnetic fields measured by the sources 201 (i.e., in response to an estimated position of an electric current 20 flowing through the current-containing volume 10). The sources 300 and sensors 201 and/or 202 can be coupled together by the computer system 299 in a feedback arrangement or as a servomechanism, so that fields are applied by the sources 300 to alter, maintain, or control the position of the current 20 in response to fields measured by the sensors 201/202. In some examples fields can be applied by the sources 300 to result in a desired transverse trajectory or distribution of the current 20. FIGS. 5 through 9 illustrate various example arrangements of sources 300 and sensors 201 on a remelting furnace 100 (including moving sources 300 in FIGS. 7A/7B and 8A/8B, and moving sensors 202 in FIGS. 8A/8B).

In the examples described above, a longitudinal actuator moves the electrode 110 downward as it melts away, to maintain a relatively constant distance across the gap 115 (because the diameter of the electrode 110 is less than the diameter of the crucible 101 and the ingot 120, the electrode 110 shrinks faster than the ingot 120 grows during the remelting process). In some examples that can be approximately achieved by, e.g., monitoring the weight of the electrode 110 (which decreases as it melts), monitoring the voltage drop across the gap 115, or monitoring a rate of drip shorts; each of those measured quantities is at least loosely correlated with the distance across the gap 115 and the length of the current segment 30 spanning the gap 115.

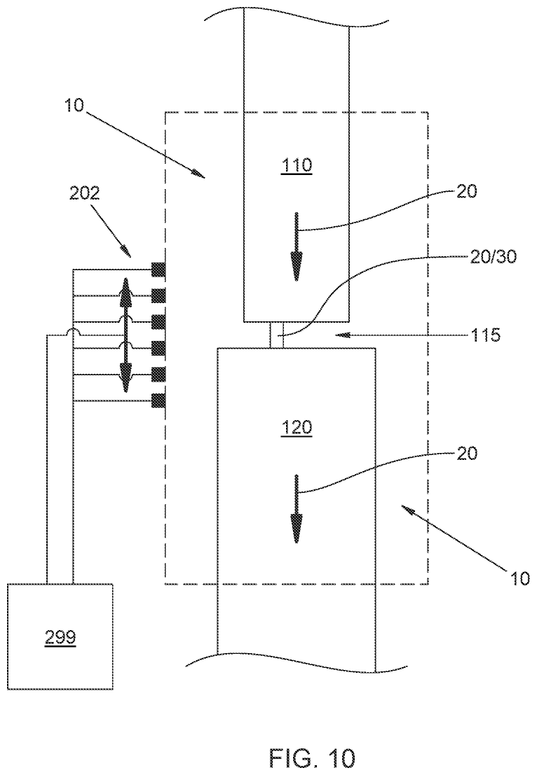

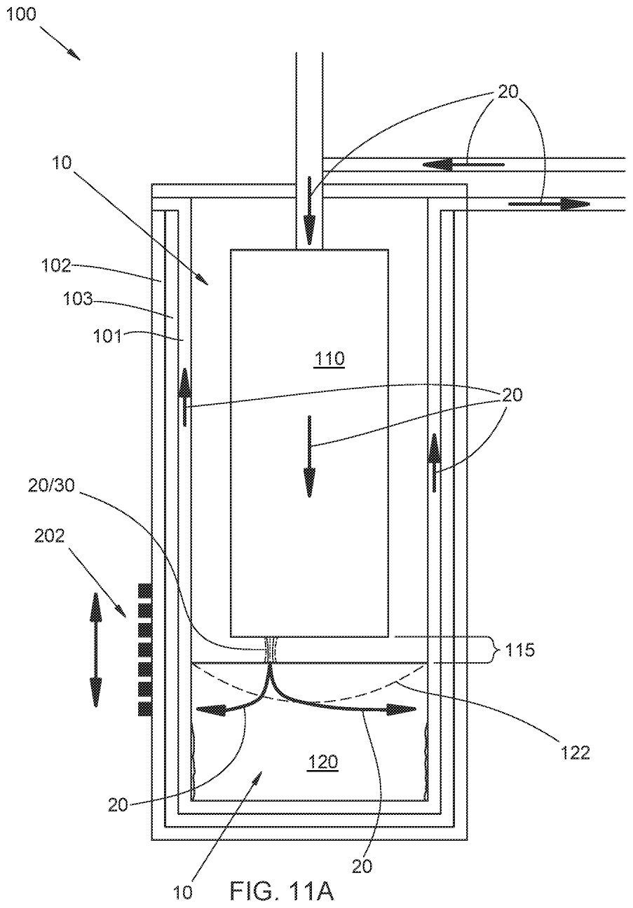

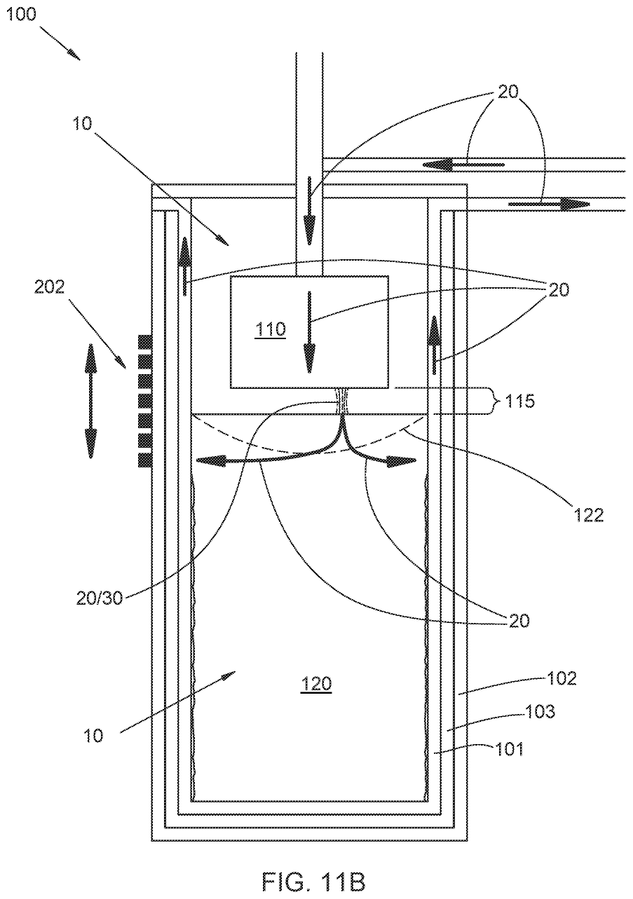

FIG. 10 illustrates schematically a general arrangement of movable magnetic field sensors 202 that move longitudinally along the current-containing volume 10. FIGS. 11A through 16B illustrate schematically various examples of a remelting furnace 100 with movable sensors 202. The movable sensors 202 typically are more closely spaced than the stationary sensors 201. An actuator or any suitable type or arrangement (e.g., hydraulic, gear-driven, servo-motor, and so forth) is arranged to move the sensors 202 and is coupled to the computer system 299 so that the sensors 202 can be moved in response to magnetic field components measured by those sensors 202, typically to keep the sensors 202 near the gap 115 as it moves along the volume 10; a feedback arrangement or servomechanism coupling the sensor actuator and the sensors 202 can be effected by the computer system 299 for that purpose. The computer system 299 can be structured and programmed to calculate an estimated length parameter that characterizes the current segment 30 (and so also characterizes the separation between the conductors 110 and 120 across the gap 115); that calculation is based at least in part on magnetic field components measured by the sensors 201 and/or 202. In some examples that length parameter can be recorded as a function of longitudinal position of the gap 115 (equivalently, longitudinal position along the ingot 120). In some examples, the sensors 202 can be operatively coupled to the longitudinal actuator 130 through the computer system 299; in some of those examples a feedback arrangement or servomechanism can be employed to maintain the length parameter at a selected value or within a selected range of values. If the furnace 100 also includes field sources 300, in some examples the sources 300 and sensors 202 (and 201 in some instances) can be used in conjunction to map out topography of the gap 115. Instead of, or in addition to, a set of sensors 202 that are movable longitudinally along the current-containing volume 10, in some examples a set of magnetic field sensors 201 can be located at fixed positions along the current-containing volume 10 with a relatively dense longitudinal spacing (e.g., as in FIGS. 1, 2, 3, and 5; longitudinal spacing can be similar to that of the movable sensors 202). The corresponding magnetic field measurements from those densely spaced sensors 201 can be used to estimate longitudinal position of the gap 115 and to estimate the length parameter(s) of one or more current segments 30.

As described in the references incorporated above, the systems, apparatus, and methods described above can be advantageously employed for process measurement and control and material characterization in a remelting furnace, e.g., a VAR furnace or an ESR furnace. Other novel and inventive methods for such process measurement and control and material characterization are disclosed hereinbelow.

It is known that solidification defects in the ingot 120 can be caused by, indicated by, and/or correlated with transient conditions arising from (i) spatial or temporal variations in heating or cooling of the melt pool 122 at the top of the ingot 120, (ii) spatial or temporal variations in current flow within the electrode 110, between the electrode 110 and the ingot 120, within the ingot 120, or between the ingot 120 and the crucible 101, or (iii) undesirable currents between the electrode 110 and the crucible 101 (e.g., as side arcs). Such variations can be particularly problematic that are not cylindrically symmetric and/or are not centered relative to the crucible 101 and the ingot 120 solidifying in it. In a VAR furnace, much of the heat deposited into the melt pool 122 arises from the electrical arc or discharge between the electrode 110 and the ingot 120 (i.e., the current segment 30) and from molten metal that drips from the electrode 110 into the melt pool 122. The transverse distribution of molten metal drips tends to reflect the transverse spatial distribution of the discharge(s) (discussed further below). In an ESR furnace, much of the heat deposited into the melt pool 122 arises from resistive heating of the slag filling the gap 115 and from molten metal that flows through the slag from the electrode 110 into the melt pool 122. Much of the heat flowing out of the melt pool 122 as it solidifies flows radially outward into the crucible 101 near the top of the growing ingot 120, and relies upon contact between the ingot 120 and the crucible 101.

Non-concentric geometry of the electrode 110 within the crucible 101 can skew the distribution of the discharge 30 and/or metal drips and/or other localized current segment(s) between the electrode 110 and the melt pool 122 across the gap 115, or can skew the distribution of heat deposited into the ingot 120 via the melt pool 122. Such non-concentric geometry can include off-center positioning of the electrode 110 within the crucible 101, tilting of the electrode with respect to the crucible 101, a bent or curved shape of the electrode 110, cracks, cavities, inclusions, or other structural irregularities within the electrode 110, or various combinations of some or all of those. As noted above, the transverse size of the electrode 110 is necessarily smaller than the transverse size of the interior of the crucible 101. If the lower end of the electrode 110 (at the gap 115) is off-center relative to the crucible 101 (and therefore also with respect to the ingot 120), the distributions of electric discharges and molten metal drips across the gap 115, or heat flow into the ingot 120, will likely also be off-center. One result can be asymmetric eroding of the lower end of the melting electrode 110 leading to an undesirable convex, concave, or tilted bottom surface of the electrode 110. Another result can be uneven, nonuniform, or asymmetric solidification of the ingot 120 that can lead to defects, inclusions, undesirable grain boundaries, or spatial variation of relative concentrations of alloying metals. It would be desirable to measure and estimate one or more of (i) the transverse position of the electrode 110 and/or its lower end within the crucible 101, (ii) the cross-sectional position and shape of the electrode 110 as a function of longitudinal position (along the electrode 110, of the gap 115 along the crucible 101, or both), or (iii) a transverse spatial distribution of the current 20 within the electrode 110 as a function of longitudinal position (along the electrode 110, along the crucible 101, or both). It would be desirable to alter, maintain, or control the estimated transverse position or angle of the electrode 110 within the crucible 101, to attain or maintain relative concentricity of one or more of (i) the current 20 flowing through the volume 10, (ii) the transverse distribution of positions of the current segment 30, or (iii) the transverse distribution of molten metal drips from the electrode 110 onto the ingot 120.

Non-concentric current flow within and between the ingot 120 and the crucible 101 can indicate irregularities during the remelting process that can result in material defects or inhomogeneities in the solidified ingot 120 (such as those discussed above). Typically the melt pool 122 solidifies radially inward from the inner surface of the crucible 101. As the ingot 120 solidifies it tends to contract and pull away from the crucible, so that much of the current flow and heat flow between the ingot 120 and crucible 101 is localized near the top of the growing ingot 120, around the melt pool 122. Detection of current flowing between the ingot 120 and the crucible 101 at positions longitudinally distant from the melt pool 122, particularly asymmetric current flow, can indicate too rapid or asymmetric cooling or solidification at that longitudinal position, possibly indicating degraded material quality in the ingot 120 at that location. Detection of asymmetric current flow near the top of the growing ingot 120 can indicate a disruption of the desired gradual, orderly solidification of the melt pool 122. For example, so-called shelf collapse or fall-in can occur wherein a portion of a partly solidified surface of the melt pool 122 breaks off and falls into the melt pool (similar to calving of icebergs from a glacier). That portion of the solidified ingot 120 typically would exhibit an increased likelihood of defects (e.g., white spots) or variations in alloy composition, and almost certainly would exhibit a higher density of undesirable grain boundaries. A transient asymmetry of the current flow into the crucible 101 at the longitudinal position of the melt pool 122 can be indicative of such a shelf-collapse event, and can indicate a transverse or longitudinal position along the solidified ingot 120 where corresponding degraded material quality might be found.

Accordingly, an inventive apparatus can include first and second longitudinal electrical conductors 110 and 120, multiple magnetic field sensors 201 and/or 202, and a computer system 299. The apparatus can be arranged as a remelting furnace 100; examples are illustrated schematically in FIGS. 1 through 18B. The first longitudinal conductor can be the electrode 110, and the second longitudinal electrical conductor can be the ingot 120. The electrode 110 and the ingot 120 are positioned end-to-end within the interior, current-containing volume 10 of the remelting furnace 100. A primary electric current 20 flows in a predominantly longitudinal direction (i) through at least portions of the electrode 110 and the ingot 120, and (ii) as one or more localized current segments 30 (e.g., primary electric discharges 30 in a VAR) spanning a gap 115 separating the electrode 110 and ingot 120. The one or more localized current segments 30 can move in two transverse dimensions within the gap 115. Multiple magnetic field sensors 201 (stationary) and/or 202 (movable) are arranged to measure magnetic field components in one or more spatial dimensions and are located at corresponding sensor positions arranged about a lateral periphery of the current-containing volume 10. The sensors 201/202 are located at multiple different longitudinal positions along the furnace 100 and multiple different circumferential positions around the furnace 100.

The computer system 299 receives from the magnetic field sensors 201 and/or 202 corresponding signals indicative of magnetic field components measured at multiple sensor positions, including sensor positions that are longitudinally offset from the arc gap 115. The computer system 299 can calculate, based at least in part on two or more of the measured magnetic field components, an estimated transverse position of the one or more current segments 30 within the gap 115. In some examples two or more magnetic field components measured at corresponding sensor positions displaced longitudinally from the gap 115 toward the electrode 110 (i.e., toward the top of the furnace 100) can be used by the computer system 299 to calculate estimated relative tilt or transverse offset of the electrode 110 or portions thereof, estimated overall shape of the electrode 110, or estimated spatial distribution of current flowing within the electrode 110 that might be affected by internal cracks, inclusions, or other electrode defects. In some examples two or more magnetic field components measured at corresponding sensor positions displaced longitudinally from the gap 115 toward the ingot 120 (i.e., toward the bottom of the furnace 100) can be used by the computer system 299 to calculate estimated spatial distribution of current within and/or between the ingot 120 and the crucible 101.

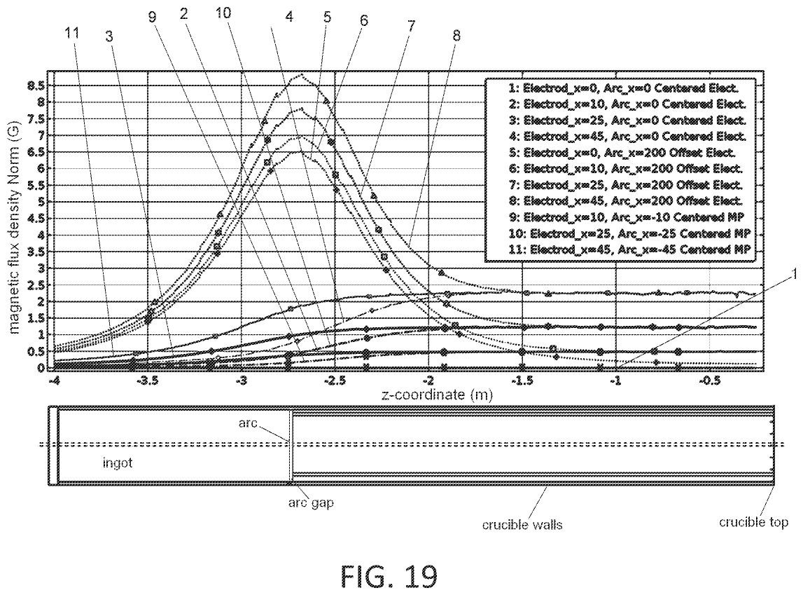

FIG. 19 includes plots of simulated longitudinal magnetic field components as a function of longitudinal position along the furnace 100, calculated using different transverse positions of a right cylindrical electrode 110 within the crucible and different transverse positions of the current segment 30 within the arc gap 115. Curve 1 is for the case wherein both the electrode 110 and the current segment 30 are centered within the crucible 101; as expected, the calculated magnitude of the longitudinal magnetic field is zero all along the furnace 100. Curves 2-4 are for 10 mm, 25 mm, and 45 mm transverse displacements, respectively, of both the electrode 110 and the current segment 30 (i.e., the current segment 30 remains centered on the electrode 110 as the electrode 110 is displaced). Curves 5-8 are for 0 mm, 10 mm, 25 mm, and 45 mm transverse displacements, respectively, of the electrode 110, with the current segment displaced 200 mm further in the same direction (i.e., off-center with respect to the electrode 110 as the electrode 110 is displaced). Curves 9-11 are for 10 mm, 25 mm, and 45 mm transverse displacements, respectively, of the electrode, with the current segment 30 remaining centered within the crucible 101.

As can be seen from the plots of FIG. 19, the longitudinal magnetic field magnitudes near the gap 115 are heavily influenced by the position of the current segment 30. Current segments farthest from the center of the crucible (curves 5-8) exhibit significant peaks in the region of the gap 115. In contrast, at positions sufficiently displaced longitudinally from the gap 115 (e.g., to the right of −1.5 m in FIG. 19), the longitudinal magnetic field magnitude depends almost entirely on the transverse offset of the electrode 110; curves representing the same displacement of the electrode 110 but different displacements of the current segment 30 converge to a common value. For a centered electrode, curves 1 and 5 converge to essentially zero longitudinal field magnitude to the right of −1 m in FIG. 19. For an electrode 110 displaced 10 mm off center, curves 2, 6, and 9 converge to about 0.5 gauss to the right of −1.5 m. For an electrode 110 displaced 25 mm off center, curves 3, 7, and 10 converge to about 1.2 gauss to the right of −1.5 m. For an electrode 110 displaced 45 mm off center, curves 4, 8, and 11 converge to about 2.2 gauss to the right of −1.5 m.

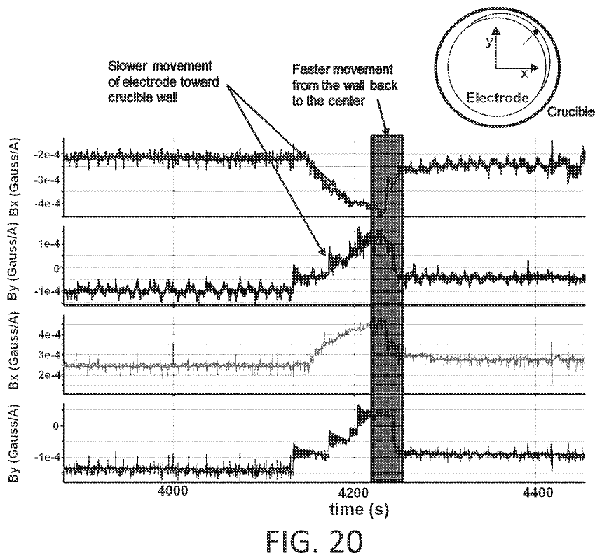

Plots of magnetic fields measured in a VAR furnace are shown in FIG. 20. Changes in magnetic field strength between 4100 sec and 4300 sec can be seen that resulted from intentional movement of the electrode 110 toward one side of the crucible 101 and back again.

The magnetic field components measured by some or all of the magnetic field sensors 201 and/or 202 can be recorded as a function of the moving longitudinal position of the gap 115 during a remelting process in the furnace 100. The longitudinal position of the gap 115 can in turn be correlated with a corresponding longitudinal position along the solidified ingot 120 after the remelting process is completed, and can therefore act as a guide to relative material quality of different portions of the ingot 120. In some examples, an estimated transverse distribution of positions within the gap 115 of the current segment 30 (e.g., an arc or discharge) or of molten metal drips (discussed below), calculated from measured magnetic field components, can be recorded as a function of longitudinal position along the solidified ingot 120 (as described herein and in several of the incorporated references). In some examples, estimated presence or absence of current flowing between the electrode 110 and the crucible 101 (e.g., as one or more side arcs) can be recorded as a function of longitudinal position along the solidified ingot 120 (as described above and in several of the incorporated references); circumferential positions of such side arcs can be recorded as well. In some examples, presence or absence of undesirable operational behaviors or conditions (e.g., a long arc, a constricted arc, or a glow), can be inferred or estimated from measured magnetic field components, and can be recorded as a function of longitudinal position along the solidified ingot 120. In some examples, a transverse distribution of current flowing within the electrode 110 can be recorded as a function of longitudinal position along the solidified ingot 120 and, in some instances, as a function of longitudinal position within the crucible 101 or along the electrode 110. Those recorded measurements can be employed, e.g., to correlate a given longitudinal position along the solidified ingot 120 with, e.g., a corresponding transverse position of the end of the electrode 110, or melting of a cracked, damaged, or otherwise irregular portion of the electrode 110. In some examples, a transverse or circumferential distribution of current flowing within and/or between the ingot 120 and the crucible 101 can be recorded as a function of longitudinal position along the solidified ingot 120 and, in some instances, as a function of longitudinal position within the crucible 101. Those recorded measurements can be employed, e.g., to correlate a given longitudinal position along the solidified ingot 120 with, e.g., a corresponding shelf-collapse event in the melt pool 122, or a portion of the ingot 120 that remained in electrical contact with the crucible after solidification.

In addition to the recording of measured magnetic field components (and estimated quantities calculated therefrom), those measured field components or calculated quantities can be employed to guide or control active measures taken to maintain, alter, or control the remelting process. In some examples, the magnetic field sources 300 can be employed to apply magnetic fields to the interior of the remelting furnace 100, typically in or near the region of the gap 115, for maintaining, altering, or controlling the transverse position of the current segment 30 within the gap 115 (as described above and in several of the incorporated references). Strength and direction of those applied fields can be determined at least in part based on measured field components or quantities calculated therefrom; in some of those examples the field sensors 201 and/or 202 can be coupled to the magnetic field sources 300 by the computer system 299 in a feedback arrangement or as a servomechanism. In some examples, detection or estimation of the presence of one or more undesirable conditions within the furnace 100 (e.g., a side arc, a long arc, a constructed arc, or a glow) can cause the computer system 299 to activate one or more magnetic field sources 300 to alter or terminate the undesirable condition.

In some examples the remelting furnace 100 can include corresponding additional sensors, that are coupled to or positioned on or in the furnace 100, that are arranged for measuring one or more or all of (i) longitudinal or transverse position or velocity of the electrode 110 or one or more actuators 130/140 coupled to the electrode 110, (ii) weight of the electrode 110, (iii) magnitude of the operating current or fluctuations thereof, (iv) a difference between the operating current and the primary current 20, (v) voltage drop between the electrode 110 and the ingot 120, or fluctuations thereof, (vi) electrical resistance across the gap 115 (e.g., through slag filling the gap 115; sometimes referred to as “swing” or “resistance swing”) or fluctuations thereof, (vii) temperature within the furnace 100, (viii) one or more temperature gradients within or along the electrode 110, within or along the ingot 120, or along or around the crucible 101, (ix) pressure or composition of gas or vapor within the furnace 100, (x) optical spectral properties light emitted by the one or more current segments 30/32, or (xi) images of an interior of the furnace 100. Signals generated by such additional sensors, indicative of corresponding measured quantities, are received by the computer system 299. In some examples, furnace operational parameters such as total current, interior vapor pressure (e.g., helium pressure between the crucible 101 and solidified portions of the ingot 120, or argon backflow pressure), interior vapor composition, slag depth or composition (in an ESR furnace) and so forth can be maintained, altered, or controlled by the computer system 299 in response to measured field components or quantities calculated therefrom. In some examples detection or estimation of the presence of undesirable operational conditions (e.g., such as those described above) can cause the computer system 299 to alter furnace operational parameters (e.g., such as those described above) to reduce or eliminate the undesirable condition. For example, detection of an undesirable glow or constricted arc might result in alteration of input gas pressure, flow, or composition. In some examples, measured magnetic field components or other furnace operational parameters (e.g., current, voltage, gas pressure or composition, excessive or insufficient movement of the electrode 110) indicative of furnace malfunction or improper set-up or operation can cause the computer system 299 to alter or terminate operation of the furnace 100.

As noted above, the remelting furnace 100 includes a longitudinal actuator 130 (shown explicitly only in FIGS. 15A-18B, but is included in any of the examples of FIGS. 1-18B) for controlling the vertical position of the electrode 110 within the crucible 101 so as to maintain a distance across the gap 115 within a desired range during the remelting process. The electrode 110 must move downward as it melts, because the ingot 120 grows more slowly than the electrode 110 shrinks during the remelting process. The longitudinal actuator 130 is connected to the computer system 299, which can control vertical (i.e., longitudinal) movement of the electrode 110 based on one or more of weight of the electrode 110, melt duration, voltage drop across the gap 115, or one or more measured magnetic field components (from which distance across the gap 115 can be estimated, as described above and in several of the incorporated references).

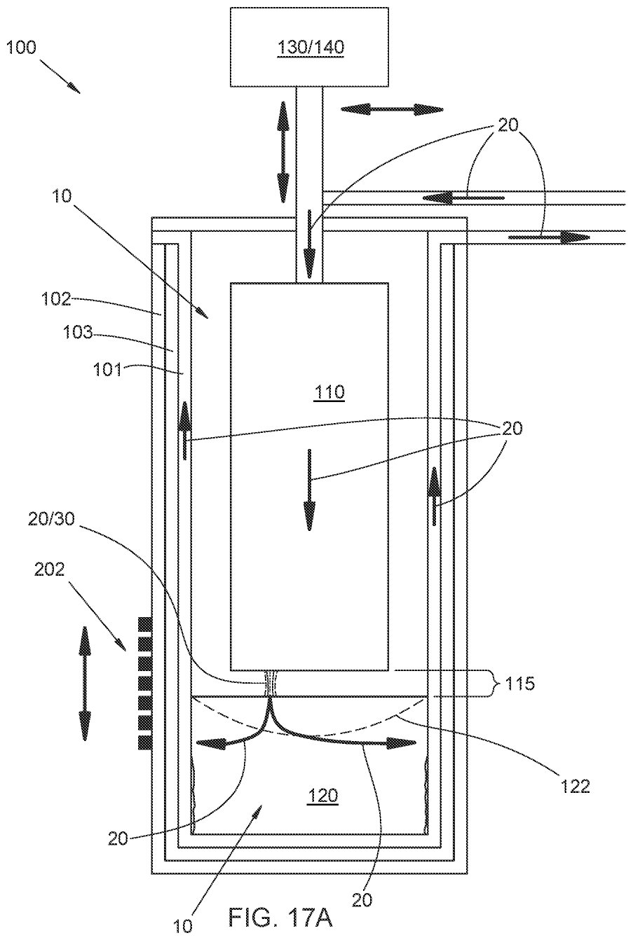

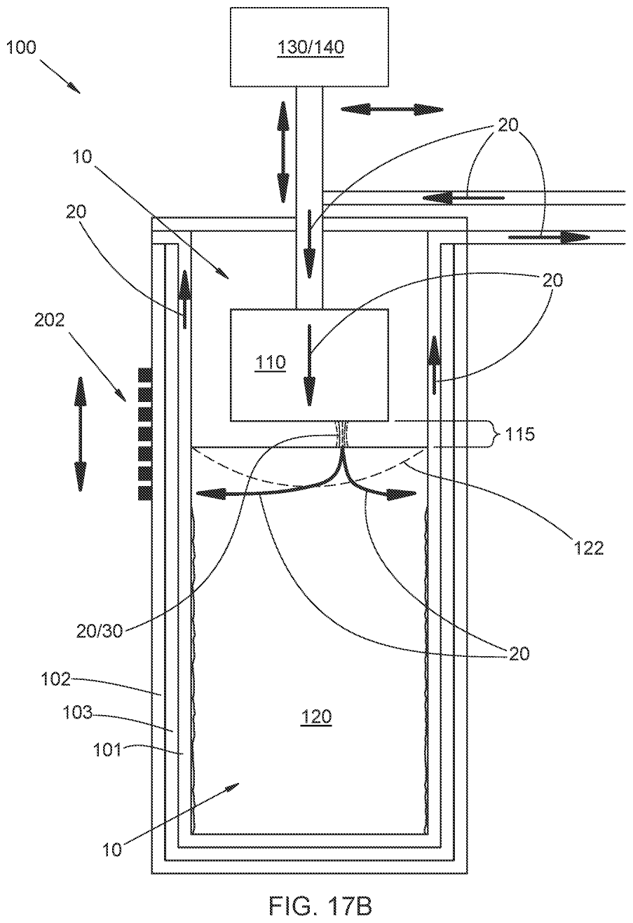

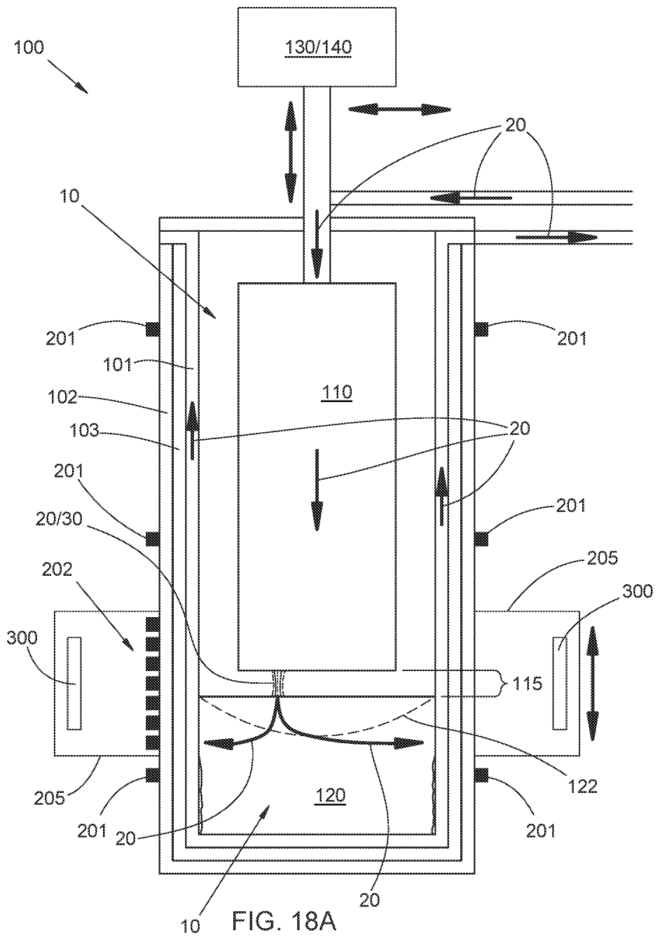

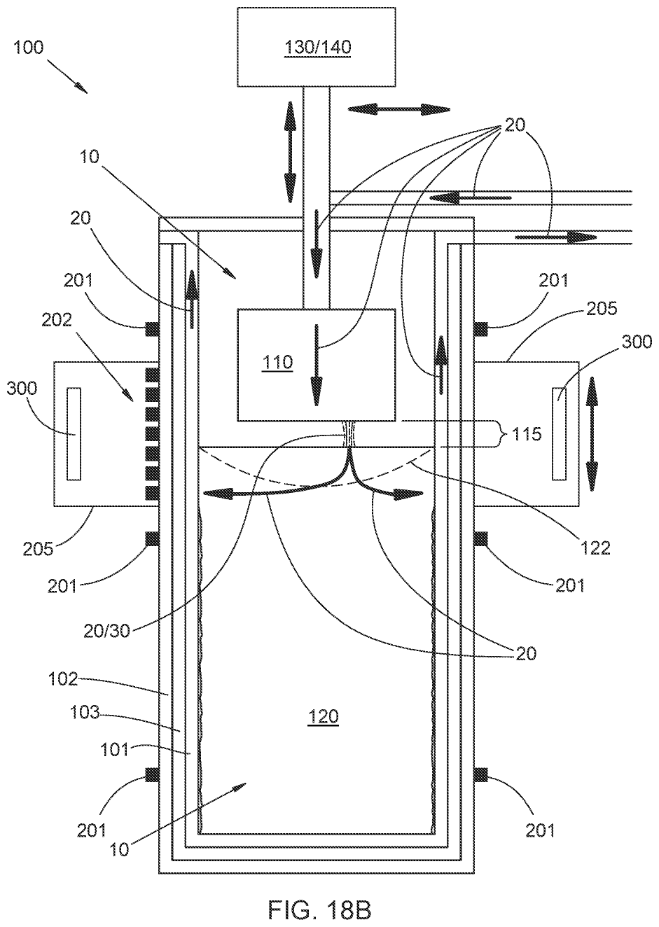

In addition to the longitudinal actuator 130, in some examples the apparatus can include a transverse actuator 140 of any suitable type or arrangement (e.g., hydraulic, gear-driven, servo-motor, and so forth). The transverse actuator 140 is shown explicitly only in FIGS. 17A-18B, but can be included in any of the examples of FIGS. 1-18B. In some examples the longitudinal and transverse actuators 130 and 140 can be combined into a single, dual-axis unit; in other examples they can comprise discrete units. The transverse actuator 140 can be arranged so as to provide one or both of (i) relative transverse movement of the electrode 110 within the crucible 101, or (ii) relative tilt of the electrode 110 within the crucible 101. The computer system 299 can generate one or more transverse-position control signals and transmit those signals to the transverse actuator 140 to effect transverse movement and/or tilt of the electrode 110. The transverse-position control signals can be based at least in part on one or both of the estimated transverse position or distribution of the current segment(s) 30, an estimated relative tilt or transverse offset of the electrode 110 within the crucible 101, or an estimated shape of the electrode 110. Those estimated positions or shapes can be calculated based on measured magnetic field components measured by the sensors 201 and/or 202, as described above. In some examples, the magnetic sensors 201 and/or 202 can be operatively coupled to the transverse actuator 140 in a feedback arrangement or as a servomechanism using the computer system 299.

In some examples (e.g., as in FIGS. 18A and 18B), the transverse actuator 140 can be used in combination with other features disclosed above, including one or more of, e.g., stationary and/or moving magnetic field sensors 201/202, the longitudinal actuator 130 coupled to the computer system 299 for altering, maintaining, or controlling distance across the gap 115, or magnetic field sources 300 coupled to the computer system 299 for altering, maintaining, or controlling transverse position or distribution of the current segment(s) 30 within the gap 115. In various examples, sensors 201 and/or 202 can be operatively coupled to any one, any two, or all three of the longitudinal actuator 130, magnetic field sources 300, or the transverse actuator 140, or other control apparatus of the furnace 100. For example, the field sources 300 can be operated to center the distribution of discharge positions within the gap 115 while the transverse actuator 140 is simultaneously employed to center the electrode 110 within the crucible 101.

Dripping of molten metal from the melting electrode 110 into the melt pool 122 at the top of the ingot 120 has been described above. In addition to estimating a transverse position, or distribution of transverse positions, of the one or more current segments 30 within the gap 115, it also would be desirable to estimate a distribution of transverse positions of drips onto the ingot 120.

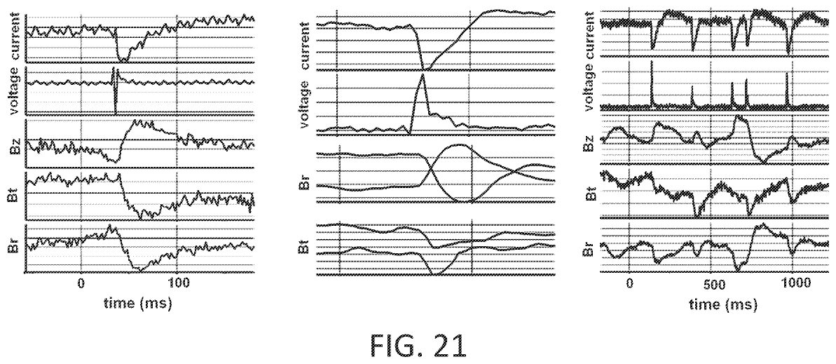

Each molten drip can cause a so-called drip short, when the dripping metal creates a transient conduction path between the electrode 110 and the ingot 120. The presence of that conduction path in turn causes transient spikes or waveforms in the voltage drop across the gap 115 or the current 20 flowing through the furnace 100. In an inventive method, magnetic field components can be measured at multiple longitudinal position along the furnace 100 and/or multiple circumferential positions around the furnace 100. Estimates of a transverse position, or a distribution of transverse position, of one or more current segments 30 can be calculated as described above. However, if drip shorts are present, those transverse position estimates are necessarily affected by the presence of those drip shorts. The computer system 299 can be connected to monitor voltage drop between the electrode 110 and the ingot 120 and the current flowing through the furnace 100. Detection of an abrupt, transient decrease in the voltage drop and an abrupt, transient increase in current is indicative of the occurrence of a drip short. Note that the transients in the furnace current and voltage might only last a few milliseconds. In some examples the sampling rate of the magnetic field sensors 201 and/or 202 can be sufficiently fast to capture those transients (e.g., 500 Hz, 1 kHz, or even faster). In other examples, lower sampling rates can be employed if time constants in the detection system are long enough that transient features are detectable at the lower sampling rate. FIG. 21 shows some examples of measured current, voltage, and magnetic field components during operation of a remelting furnace; the transient features in the voltage and current traces are clearly visible, as are corresponding transient features in the magnetic field traces.

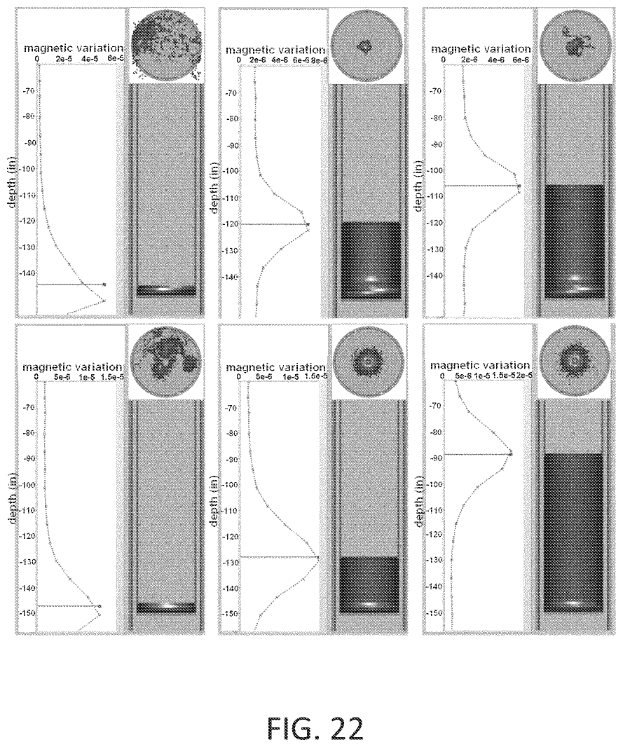

The computer system can compute an estimated transverse position of the current segment 30 (as described above) using magnetic field component measured at the time of the detected voltage and current transients. However, the estimated position thus calculated is indicative of the position of the drip short that caused those voltage and current transients, rather than an electrical discharge. During the remelting process, for each detected drip short a corresponding estimated longitudinal position (the longitudinal position of the gap 115 at the time of the drip short) and a corresponding transverse position (calculated from the measured field components at the time of the drip short) can be recorded for the ingot 120. Two examples are shown in FIG. 22.

While the transverse position of a drip short cannot be controlled, an average distribution of drip shorts can be altered, maintained, or controlled using magnetic field sources 300 described above. Drip shorts occur where melting occurs on the electrode 110, which is heated by the one or more current segments (e.g., discharges 30). Using the field sources 300 to alter, maintain, or control the position or distribution of the current segment(s) 30 (as described above), the transverse spatial distribution of drip shorts also can be altered, maintained, or controlled (at least on average; the formation of drip shorts is a somewhat random process). The computer system 299 can monitor the occurrence and distribution of drip shorts and can cause the sources 300 to apply magnetic fields to alter, maintain, or control (indirectly) the drip short spatial distribution. In some examples the field sources 300 can be employed to move the discharge(s) 30, or the distribution of drip shorts, to spread out deposition of heat into the melt pool 122 of the ingot 120. In some examples, the magnetic field sources can be operated to move the discharge(s) or drip short distribution in, e.g., a spiral, circular, or star pattern to achieve that result. In some examples spreading out the heat distribution can result in an ingot 120 with improved “skin quality”, i.e., a thinner layer of metal around the circumference of the solidified ingot 120 that must be later removed due to its low quality.

The inventive method for measuring positions or distributions of drip shorts can be used in combination with other features disclosed above, including one or more of, e.g., stationary and/or moving magnetic field sensors 201/202, the longitudinal actuator 130 coupled to the computer system 299 for altering, maintaining, or controlling distance across the gap 115, magnetic field sources 300 coupled to the computer system 299 for altering, maintaining, or controlling transverse position or distribution of the electric current segment(s) 30 within the gap 115, or the transverse actuator 140 coupled to the computer system for altering, maintaining, or controlling transverse position of the electrode 110 within the crucible 101.

As noted above, in some examples the remelting furnace 100 can include additional sensors for measuring or detecting various characteristics of the furnace 100 or the remelting process occurring therein. The computer system 299 can receive signals indicative of some or all of the magnetic field components measured using the sensors 201 and/or 202, and/or can receive signals indicative of some or all of the quantities measured by the additional sensors. In some examples, based at least in part on some or all of those received signals, or on quantities or parameters calculated, estimated, or derived therefrom (e.g., transverse or longitudinal positions or distribution of current segments 30), the computer system 299 can be used for altering, maintaining, or controlling one or more operating parameters of the furnace 100 during the remelting process. In some examples, based at least in part on some or all of those received signals, or on quantities or parameters calculated, estimated, or derived therefrom, the computer system 299 can be used for generating and storing a longitudinal or three-dimensional map of the ingot 120 produced by the remelting process.

In some examples, altering, maintaining, or controlling one or more operating parameters of the furnace 100 during the remelting process can include one or more of: (i) aborting the remelting process; (ii) temporarily interrupting and then restarting the remelting process; (iii) rejecting or downgrading the ingot or only selected portions thereof; (iv) specifying or recommending specific post-melt processing of the ingot or only specific portions thereof; (v) applying a magnetic field to alter, maintain, or control transverse position or distribution of one or more current segments within the gap 115; (vi) applying a magnetic field to alter, maintain, or control transverse distribution of multiple drip shorts within the gap 115; (vii) applying a magnetic field to alter, maintain, or control transverse distribution of heat deposited on a surface of the ingot; (viii) applying a magnetic field to attenuate or terminate a side arc, constricted arc, glow, or long arc; (ix) alter, maintain, or control distance between the electrode and the ingot across the gap 115; (x) alter, maintain, or control angle or transverse position of the electrode 110 within the crucible 101; (xi) alter, maintain, or control voltage across the gap 115; (xii) alter, maintain, or control current flowing through the electrode 110 and the ingot 120; (xiii) alter, maintain, or control electrical resistance across the gap 115 (e.g., through molten slag filling the gap 115; sometimes referred to as “swing” or “resistance swing”); (xiv) alter, maintain, or control immersion depth of the electrode 110 into molten slag filling the gap 115; or (xv) alter, maintain, or control gas pressure or composition within the furnace 100.

Measurements of magnetic field components and/or other characteristics of the furnace 100 or the remelting process occurring therein can be recorded as a function of time during the remelting process, which corresponds to a longitudinal position along the ingot 120. In some examples, one or more of the following can be recorded as a function of longitudinal position along the ingot 120 formed by a remelting process within the remelting furnace 100: (i) transverse position or distribution of one or more current segments; (ii) transverse position or distribution of multiple drip shorts; (iii) angle or transverse position of the electrode within the crucible; (iv) distance across the gap 115 between the electrode 110 and the ingot 120; (v) a surface profile of the electrode 110 obtained by estimating distance across the gap 115 as a function of transverse position of the current segment 30; (vi) presence or duration or position of one or more side arcs 32; (vii) presence or duration or position of one or more constricted arcs, glows, or long arcs; (viii) detection of presence or position of a crack or defect in the electrode during a corresponding temporal portion of the remelting process that produced the ingot, (ix) longitudinal shape of the electrode, (x) gas pressure or composition within the furnace, (xi) slag depth or composition within the furnace, (xii) occurrence or position of a shelf-collapse event into the melt pool, or (xiii) transient fluctuations of current or voltage across the gap 115.

One or more of those measured quantities can be used to generate and store a map of the ingot 120, the map indicating, as a function of longitudinal or three-dimensional position within the ingot 120, remelting conditions, metal quality, or specified or recommended post-melt processing. For example, metal quality as a function of position in the ingot 120 can be classified based on suitability of the metal for subsequent uses, e.g., jet turbine blades or nuclear power plants versus golf clubs. Note that higher- and lower-quality metal can be obtained from the same ingot 120 and directed to different end uses, reducing waste or need for further remelting. In another example, metal of the ingot 120 can be classified (as a function of position) based on suitability for different post-melt processing steps (e.g., machining versus extrusion versus hot- or cold-forging).

In some examples, conventional computer algorithms can be executed by the computer system 299 for controlling the remelting process and/or for mapping the resulting ingot 120. In some examples, quantities measured by magnetic field sensors 201 or 202 by other, additional sensors can be used as direct inputs to a process control algorithm, or recorded as part of the ingot map. In some examples, quantities estimated, calculated, derived from measured quantities can be employed, e.g., a spatial distribution of drip shorts estimated from magnetic field and voltage measurements, or side arc position estimated from magnetic field measurements and differences between input and primary currents.

In some examples, the computer system 299 can include an artificial intelligence subsystem (Al), a machine learning subsystem (ML), or a neural network (NN). In such examples, the Al, ML, or NN can be provided with training data that includes (i) signals received from the magnetic field sensors 201 and/or 202 and additional sensors during multiple remelting processes, and (ii) observed or measured metal quality as a function of three-dimensional position within the corresponding ingots 120 produced by those multiple remelting processes. In some examples the training data can include magnetic field components applied by the sources 300. In some examples the signals of the various sensors serve as the training data; in other examples, quantities estimated, calculated, or derived from the sensor signals (e.g., estimated positions or distributions of current segments 30) can be included in the training data. Once the Al, ML, or NN has been adequately trained, in some examples it can be used for altering, maintaining, or controlling one or more operating parameters of the furnace 100 during the subsequent remelting process, in response to signals received from the various sensors during that process. In some examples, the trained Al, ML, or NN can be employed for mapping the ingot 120 based on signals received from the various sensors during the remelting process that produced that ingot 120. In some examples, the Al, ML, or NN can be employed for both purposes. In some examples the Al, ML, or NN can employ so-called explainable algorithms, so that behavior of the computer system 299 during the remelting process or the mapping of the ingot 120 can be analyzed and understood; in other examples, such analysis might not be possible to extract from the Al, ML, or NN. In some examples the Al, ML, or NN system can be trained to recognize and locate (longitudinally, or in three-dimensions) anomalies that occur during a remelting process during operation of the furnace 100. Anomaly detection can be implemented in any suitable way, including, e.g., observation of changes to mean or standard deviation (or other statistical parameter(s)) of one or more measured or estimated/calculated/derived quantities, or a temporal frequency of such changes.

A few specific examples can be illustrative. In a first specific example, magnetic field measurements (e.g., vertical component near the gap 115), furnace gas composition (e.g., copper detected by mass spectrometry), or spectral properties of light generated within the furnace 100 (e.g., atomic copper emission) can be indicative of a side arc at a given longitudinal and circumferential position of the ingot 120. The computer system 299 might alter magnetic fields applied by the source 300 and temporarily reduce the voltage across the gap 115 until evidence of the side arc 32 subside or disappear, and then return the furnace 100 to the previous operating conditions. Instead or in addition, the map of the ingot 120 can indicate that a volume of metal around the estimated position of the side arc 32 is to be discarded. In a second specific example, magnetic field measurements (both near to and longitudinally displaced from the gap 115) and voltage measurements can be indicative of a distribution of drip shorts skewed toward an edge of the ingot 120 and corresponding transverse displacement of the electrode 110 (which might also be indicated by images acquired within the furnace 100). The computer system 299 might later the transverse position or tilt of the electrode 110 to recenter the drip short distribution, with or without applying a magnetic field using one or more of the sources 300, as needed. Instead or in addition, the map of the ingot 120 can indicate that a volume of metal around the observed skewed distribution of drip shorts be downgraded for use in only non-critical applications. In a third specific example, asymmetric heating of the crucible 101 near the gap 115, asymmetric current flow into the crucible 101 near the gap 115, or images acquired within the furnace 100 can be indicative of a so-called shelf-collapse event. The map of the ingot 120 can indicate that a volume of metal around the estimated position of the shelf collapse is to be discarded. Myriad other examples can be implemented within the scope of the present disclosure or appended claims.

The remelting process control and ingot mapping enabled by the disclosed apparatus and methods provide several advantages, including but not limited to one or more of enhanced safety, higher overall material quality, reduced waste of substandard ingot material, and so forth.

The systems and methods disclosed herein can be implemented as or with general or special purpose computers or servers or other programmable hardware devices programmed through software, or as hardware or equipment “programmed” through hard wiring, or a combination of the two. A “computer” or “server” can comprise a single machine or can comprise multiple interacting machines (located at a single location or at multiple remote locations). Computer programs or other software code, if used, can be implemented in tangible, non-transient, temporary or permanent storage or replaceable media, such as by including programming in microcode, machine code, network-based or web-based or distributed software modules that operate together, RAM, ROM, CD-ROM, CD-R, CD-R/W, DVD-ROM, DVD±R, DVD±R/W, hard drives, thumb drives, flash memory, optical media, magnetic media, semiconductor media, or any future computer-readable storage alternatives. Electronic indicia of a dataset can be read from, received from, or stored on any of the tangible, non-transitory computer-readable media mentioned herein.

In addition to the preceding, the following example embodiments fall within the scope of the present disclosure or appended claims. Any given Example below that refers to multiple preceding Examples shall be understood to refer to only those preceding Examples with which the given Example is not inconsistent, and to exclude implicitly those preceding Examples with which the given Example is inconsistent.

Example 1. An apparatus comprising: (a) first and second longitudinal electrical conductors positioned end-to-end within a current-containing volume through which a primary electric current flows in a predominantly longitudinal direction (i) through at least portions of the first and second conductors, and (ii) as one or more transversely localized electric current segments spanning a gap separating the first and second conductors, the one or more current segments being movable in two transverse dimensions within the gap; (b) multiple magnetic field sensors (i) arranged to measure magnetic field components in one or more spatial dimensions or magnetic field magnitude, and (ii) located at corresponding sensor positions arranged about a lateral periphery of the current-containing volume at multiple different longitudinal positions and multiple different circumferential positions; and (c) computer system comprising one or more electronic processors and one or more digital storage media coupled thereto, the computer system being structured, connected, and programmed so as to (i) receive from the magnetic field sensors corresponding signals indicative of magnetic field components measured at multiple corresponding sensor positions longitudinally offset from the gap, and (ii) based at least in part on two or more of the measured magnetic field components, calculate an estimated transverse spatial distribution of current within or through one or both of the first and second conductors.

Example 2. The apparatus of Example 1 wherein at least one of the current segments is an electric discharge or arc formed across the gap between the first and second conductors.

Example 3. The apparatus of Example 1, the current-containing volume being an interior volume of a remelting furnace, the first conductor being an electrode of the remelting furnace, and the second conductor being an ingot formed by a remelting process in a crucible of the remelting furnace.

Example 4. The apparatus of Example 3 wherein at least one of the one or more current segments is an electric discharge or arc formed across the gap between the electrode and the ingot.

Example 5. The apparatus of any one of Examples 3 or 4 wherein at least one of the current segments is a transient short circuit through a droplet of molten metal that drips across the gap between the electrode and the ingot.

Example 6. The apparatus of any one of Examples 3 through 5 wherein a layer of molten slag at least partially fills the gap between the electrode and the ingot, and the one or more current segments pass through the slag layer.

Example 7. The apparatus of any one of Examples 3 through 6, the computer system being structured, connected, and programmed so as to calculate, based at least in part on two or more of the measured magnetic field components, a longitudinal or transverse position of a shelf-collapse event of a solidifying portion of a melt pool at a top surface of the ingot.

Example 8. The apparatus of any one of Examples 1 through 7, the computer system being further structured, connected, and programmed so as to (i) receive from the magnetic field sensors corresponding signals indicative of magnetic field components measured at multiple corresponding sensor positions, (ii) based at least in part on two or more of the measured magnetic field components, calculate an estimated transverse position or distribution of the one or more current segments within the gap.

Example 9. The apparatus of any one of Examples 1 through 8 further comprising a transverse actuator arranged so as to provide transverse or angular movement of the first or second conductors relative to one another, the computer system being further structured, connected, and programmed so as to (i) generate one or more transverse-position control signals, based at least in part on one or both of the estimated transverse position or distribution of the one or more primary electric discharges or the estimated relative transverse offset of the first and second conductors, and (ii) transmit to the transverse actuator the one or more transverse-position control signals so as to alter, maintain, or control relative transverse position or angle of the first and second conductors.

Example 10. The apparatus of any one of Examples 1 through 9 further comprising a longitudinal actuator arranged so as to provide longitudinal movement of the first or second conductors relative to one another, the computer system being further structured, connected, and programmed so as to (i) calculate, based at least in part on two or more of the measured magnetic field components, an estimated gap distance between the first and second conductors, (ii) generate one or more longitudinal-position control signals, based at least in part on the estimated gap distance, and (ii) transmit to the longitudinal actuator the one or more longitudinal-position control signals so as to alter, maintain, or control an estimated gap distance between the first or second conductors.

Example 11. The apparatus of any one of Examples 1 through 10 further comprising one or more magnetic field sources located at corresponding source positions arranged about the lateral periphery of the current-containing volume and arranged so as to apply a corresponding applied magnetic field having a corresponding non-zero component directed transversely across at least a portion of the current-containing volume that includes the gap, the computer system being further structured, connected, and programmed so as to (i) generate one or more applied-field control signals, based at least in part on one or both of the estimated transverse position or distribution of the one or more current segments within the gap, and (ii) transmit to the magnetic field sources the one or more applied-field control signals so as to alter, maintain, or control a position or distribution of the one or more current segments within the gap.

Example 12. The apparatus of any one of Examples 1 through 11, the computer system being structured, connected, and programmed so as to calculate, based at least in part on two or more of the measured magnetic field components, (i) an estimated relative transverse offset or relative angle of the first and second conductors, (ii) a longitudinal shape profile of one or both of the first or second conductors, or (iii) corresponding positions, sizes, or shapes of one or more cracks, inclusions, cavities, or structural defects within one or both of the first or second conductors.

Example 13. The apparatus of any one of Examples 3 through 12 wherein the computer system is structured, connected, and programmed so as to (i) receive from the magnetic field sensors corresponding signals indicative of magnetic field components measured at multiple corresponding sensor positions, (ii) receive signals indicative of magnitude of the primary electric current and furnace voltage across the electrode and ingot, (iii) detect a drip short between the electrode and the ingot based on measured transient deviations in the primary electric current or the furnace voltage indicative of a drip short, and (iv) based at least in part on two or more of the magnetic field components measured at the time of the detected drip short, calculate an estimated transverse position of the detected drip short within the gap.

Example 14. An apparatus comprising: (a) a longitudinal first conductor, arranged as an electrode, and a longitudinal second conductor, arranged as an ingot, positioned end-to-end within a current-containing volume within an arc furnace through which a primary electric current flows in a predominantly longitudinal direction (i) through at least portions of the electrode and ingot, and (ii) as one or more primary electric discharges spanning a gap separating the electrode and the ingot, the one or more primary discharges being movable in two transverse dimensions within the gap; (b) multiple magnetic field sensors (i) arranged to measure magnetic field components in two or more spatial dimensions and (ii) located at corresponding sensor positions arranged about a lateral periphery of the arc furnace at multiple different longitudinal positions and multiple different circumferential positions; and (c) computer system comprising one or more electronic processors and one or more digital storage media coupled thereto, the computer system being structured, connected, and programmed so as to (i) receive from the magnetic field sensors corresponding signals indicative of magnetic field components measured at multiple corresponding sensor positions, (ii) receive signals indicative of magnitude of the primary electric current and furnace voltage across the electrode and ingot, (iii) detect a drip short between the electrode and the ingot based on measured transient deviations in the primary electric current or the furnace voltage indicative of a drip short, and (iv) based at least in part on two or more of the magnetic field components measured at the time of the detected drip short, calculate an estimated transverse position of the detected drip short within the gap.

Example 15. The apparatus of any one of Examples 13 or 14, the computer system being further structured, connected, and programmed so as to calculate estimated transverse positions for multiple detected drip shorts and to calculate a transverse spatial distribution of those multiple estimated drip short positions.

Example 16. The apparatus of any one of Examples 13 through 15, the computer system being further structured, connected, and programmed so as to (i) receive from the magnetic field sensors corresponding signals indicative of magnetic field components measured at multiple corresponding sensor positions, and (ii) based at least in part on two or more of the measured magnetic field components, calculate an estimated transverse position or distribution of the one or more primary electric discharges within the gap.

Example 17. The apparatus of any one of Examples 13 through 16 further comprising one or more magnetic field sources located at corresponding source positions arranged about the lateral periphery of the arc furnace and arranged so as to apply a corresponding applied magnetic field having a corresponding non-zero component directed transversely across at least a portion of the arc furnace that includes the gap, the computer system being further structured, connected, and programmed so as to (i) generate one or more applied-field control signals, based at least in part on one or both of the estimated distribution of drip shorts or the estimated transverse position or distribution of the one or more primary electric discharges, and (ii) transmit to the magnetic field sources the one or more applied-field control signals so as to alter, maintain, or control a position or distribution of the one or more primary discharges which in turn alters, maintains, or controls the distribution of drip shorts.

Example 18. The apparatus of any one of Examples 1 through 17 further comprising one or more magnetic field sources located at corresponding source positions arranged about the lateral periphery of the current-containing volume and arranged so as to apply a corresponding applied magnetic field having a corresponding non-zero component directed transversely across at least a portion of the current-containing volume that includes the gap, the computer system being further structured, connected, and programmed so as to (i) generate one or more applied-field control signals, based at least in part on one or both of the estimated transverse position or distribution of the one or more current segments, and (ii) transmit to the magnetic field sources the one or more applied-field control signals so as to alter, maintain, or control a transverse position or distribution of the one or more current segments within the gap.

Example 19. The apparatus of any one of Examples 17 or 18 wherein the one or more magnetic field sources include one or more stationary sources.

Example 20. The apparatus of any one of Examples 17 through 19 wherein the one or more magnetic field sources include one or more sources moveable longitudinally along the current-containing volume.

Example 21. The apparatus of any one of Examples 1 through 20 wherein the multiple magnetic field sensors include one or more stationary sensors.

Example 22. The apparatus of any one of Examples 1 through 21 wherein the multiple magnetic field sensors include one or more sensors moveable longitudinally along the current-containing volume.

Example 23. The apparatus of any one of Examples 1 through 22, calculations based on magnetic field components measured by the sensors including corrections for one or more of (i) fields arising from external conductors carrying current to or from the first and second conductors, (ii) Earth's magnetic field, (iii) other external magnetic fields, or (iv) misalignment of one or more sensors.

Example 24. The apparatus of any one of Examples 3 through 23 further comprising corresponding additional sensors coupled to or positioned on or in the furnace and arranged for measuring one or more or all of (i) longitudinal or transverse position or velocity of the electrode or one or more actuators coupled to the electrode, (ii) weight of the electrode, (iii) magnitude of the operating current or fluctuations thereof, (iv) a difference between the operating current and the primary current, (v) voltage drop between the electrode and the ingot, or fluctuations thereof, (vi) electrical resistance across the gap, or fluctuations thereof, (vii) temperature within the furnace, (viii) one or more temperature gradients within or along the electrode, within or along the ingot, or along or around the crucible, (ix) pressure or composition of gas or vapor within the furnace, (x) optical spectral properties light emitted by the one or more current segments, or (xi) images of an interior of the furnace.

Example 25. A method employing the apparatus of any one of Examples 3 through 24, the method comprising recording, as a function of longitudinal position along the ingot formed by a remelting process within the remelting furnace, one or more of: (i) transverse position or distribution of one or more current segments; (ii) transverse position or distribution of multiple drip shorts; (iii) angle or transverse position of the electrode within the crucible; (iv) distance across the gap between the electrode and the ingot; (v) a surface profile of the electrode obtained by estimating distance across the gap as a function of transverse position of the current segment; (vi) presence or duration or position of one or more side arcs; (vii) presence or duration or position of one or more constricted arcs, glows, or long arcs; (viii) detection of presence or position of a crack or defect in the electrode during a corresponding temporal portion of the remelting process that produced the ingot, (ix) longitudinal shape of the electrode, (x) gas pressure or composition within the furnace, (xi) slag depth or composition within the furnace, (xii) occurrence or position of a shelf-collapse event into the melt pool, (xiii) transient fluctuations of current or voltage or electrical resistance across the gap, (xiv) immersion depth of the electrode into molten slag filling the gap, (xv) measured magnetic field components, or (xvi) applied magnetic field components.

Example 26. A method employing the apparatus of any one of Examples 3 through 24, the method comprising, in response to one or more magnetic field components measured by one or more corresponding sensors during a remelting process, or one or more estimated quantities calculated therefrom, performing one or more of: (i) aborting the remelting process; (ii) temporarily interrupting and then restarting the remelting process; (iii) rejecting or downgrading the ingot; (iv) rejecting or downgrading only selected portions of the ingot; (v) applying a magnetic field to alter, maintain, or control transverse position or distribution of one or more current segments within the gap; (vi) applying a magnetic field to alter, maintain, or control transverse distribution of multiple drip shorts within the gap; (vii) applying a magnetic field to alter, maintain, or control transverse distribution of heat deposited on a surface of the ingot; (viii) applying a magnetic field to attenuate or terminate a side arc, constricted arc, glow, or long arc; (ix) altering, maintaining, or controlling distance between the electrode and the ingot across the gap; (x) altering, maintaining, or controlling angle or transverse position of the electrode within the crucible; (xi) altering, maintaining, or controlling voltage across the gap; (xii) altering, maintaining, or controlling electrical resistance across the gap; (xiii) altering, maintaining, or controlling current flowing through the electrode and the ingot; (xiv) altering, maintaining, or controlling immersion depth of the electrode into molten slag filling the gap; or (xv) altering, maintaining, or controlling gas pressure or composition within the furnace.

Example 27. A method employing the apparatus of Example 24, the method comprising: (a) during a remelting process using the remelting furnace, delivering an operating electric current to the furnace, at least a portion of the operating electric current flowing through the furnace as the primary electric current; (b) using the multiple magnetic field sensors, measuring magnetic field components in one or more spatial dimensions or magnetic field magnitudes at some or all of the corresponding sensor positions as a function of time during the remelting process; (c) using the corresponding additional sensors, measuring, as a function of time during the remelting process, one or more or all of (i) longitudinal or transverse position or velocity of the electrode or one or more actuators coupled to the electrode, (ii) weight of the electrode, (iii) magnitude of the operating current or fluctuations thereof, (iv) a difference between the operating current and the primary current, (v) voltage drop between the electrode and the ingot, or fluctuations thereof, (vi) electrical resistance across the gap, or fluctuations thereof, (vii) temperature within the furnace, (viii) one or more temperature gradients within or along the electrode, within or along the ingot, or along or around the crucible, (ix) pressure or composition of gas or vapor within the furnace, (x) optical spectral properties light emitted by the one or more current segments, (xi) immersion depth of the electrode into molten slag filling the gap, or fluctuations thereof, or (xii) images of an interior of the furnace; and (d) using the computer system (i) receiving signals indicative of some or all of the magnetic field component measured in part (b), (ii) receiving signals indicative of some or all of the quantities measured in part (c), and one or both of (iii) based at least in part on the received signals or parts (b) or (c), or on quantities or parameters calculated, estimated, or derived therefrom, altering, maintaining, or controlling one or more operating parameters of the furnace during the remelting process, or (iv) based at least in part on the received signals of parts (b) or (c), or on quantities or parameters calculated, estimated, or derived therefrom, generating and storing a longitudinal or three-dimensional map of the ingot produced by the remelting process.

Example 28. A method comprising: (a) during a remelting process using a remelting furnace, delivering an operating electric current to the furnace, at least a portion of the operating electric current flowing as a primary electric current in a generally longitudinal direction (i) through at least a portion of a metal electrode positioned within a crucible of the remelting furnace, (ii) through at least a portion of a metal ingot formed within the crucible by melting of the electrode during the remelting process, and (iii) as one or more transversely localized electric current segments spanning a gap separating the electrode and the ingot, the one or more current segments being movable in two transverse dimensions within the gap; (b) using multiple magnetic field sensors located at corresponding stationary or movable sensor positions arranged about a lateral periphery of the crucible at multiple different longitudinal positions and multiple different circumferential positions, measuring magnetic field components in one or more spatial dimensions or magnetic field magnitudes at some or all of the corresponding sensor positions as a function of time during the remelting process; (c) using corresponding sensors coupled to or positioned on or in the furnace, measuring, as a function of time during the remelting process, one or more or all of (i) longitudinal or transverse position or velocity of the electrode or one or more actuators coupled to the electrode, (ii) weight of the electrode, (iii) magnitude of the operating current or fluctuations thereof, (iv) a difference between the operating current and the primary current, (v) voltage drop between the electrode and the ingot, or fluctuations thereof, (vi) electrical resistance across the gap, or fluctuations thereof, (vii) temperature within the furnace, (viii) one or more temperature gradients within or along the electrode, within or along the ingot, or along or around the crucible, (ix) pressure or composition of gas or vapor within the furnace, (x) optical spectral properties light emitted by the one or more current segments, (xi) immersion depth of the electrode into molten slag filling the gap, or fluctuations thereof, or (xii) images of an interior of the furnace; and (d) using a computer system that comprises one or more electronic processors and one or more digital storage media coupled thereto, and that is structured, connected, and programmed therefor, (i) receiving signals indicative of some or all of the magnetic field component measured in part (b), (ii) receiving signals indicative of some or all of the quantities measured in part (c), and one or both of (iii) based at least in part on the received signals or on quantities or parameters calculated, estimated, or derived therefrom, altering, maintaining, or controlling one or more operating parameters of the furnace during the remelting process, or (iv) based at least in part on the received signals or on quantities or parameters calculated, estimated, or derived therefrom, generating and storing a longitudinal or three-dimensional map of the ingot produced by the remelting process.

Example 29. The method of any one of Examples 27 or 28 comprising, based at least in part on the received signals or on quantities or parameters calculated, estimated, or derived therefrom, performing during the remelting process one or more of: (i) aborting the remelting process; (ii) temporarily interrupting and then restarting the remelting process; (iii) rejecting or downgrading the ingot or only selected portions thereof; (iv) specifying or recommending specific post-melt processing of the ingot or only specific portions thereof; (v) applying a magnetic field to alter, maintain, or control transverse position or distribution of one or more current segments within the gap; (vi) applying a magnetic field to alter, maintain, or control transverse distribution of multiple drip shorts within the gap; (vii) applying a magnetic field to alter, maintain, or control transverse distribution of heat deposited on a surface of the ingot; (viii) applying a magnetic field to attenuate or terminate a side arc, constricted arc, glow, or long arc; (ix) alter, maintain, or control distance between the electrode and the ingot across the gap, or immersion depth of the electrode into molten slag filling the gap; (x) alter, maintain, or control angle or transverse position of the electrode within the crucible; (xi) alter, maintain, or control voltage across the gap; (xii) alter, maintain, or control electrical resistance across the gap; (xiii) alter, maintain, or control current flowing through the electrode and the ingot; or (xiv) alter, maintain, or control gas pressure or composition within the furnace.

Example 30. The method of any one of Examples 27 through 29, the method comprising recording, as a function of longitudinal position along the ingot formed by a remelting process within the remelting furnace, one or more of: (i) transverse position or distribution of one or more current segments; (ii) transverse position or distribution of multiple drip shorts; (iii) angle or transverse position of the electrode within the crucible; (iv) distance across the gap between the electrode and the ingot; (v) a surface profile of the electrode obtained by estimating distance across the gap as a function of transverse position of the current segment; (vi) presence or duration or position of one or more side arcs; (vii) presence or duration or position of one or more constricted arcs, glows, or long arcs; (viii) detection of presence or position of a crack or defect in the electrode during a corresponding temporal portion of the remelting process that produced the ingot, (ix) longitudinal shape of the electrode, (x) gas pressure or composition within the furnace, (xi) slag depth or composition within the furnace, (xii) occurrence or position of a shelf-collapse event into the melt pool, (xiii) transient fluctuations of current or voltage or electrical resistance across the gap, (xiv) one or more magnetic field components; (xv) one or more applied magnetic field components, or (xvi) immersion depth of the electrode into molten slag filling the gap.

Example 31. The method of Example 30, the map indicating, as a function of longitudinal or three-dimensional position within the ingot, remelting conditions, metal quality, or specified or recommended post-melt processing.

Example 32. The method of any one of Examples 25 through 31 wherein the computer system includes an artificial intelligence subsystem, a machine learning subsystem, or a neural network, the method further comprising: (A) providing as training data to the artificial intelligence subsystem, the machine learning subsystem, or the neural network (i) the received signals of parts (b) and (c) for multiple remelting processes, and (ii) observed or measured metal quality as a function of three-dimensional position within the corresponding ingots produced by the multiple remelting processes; (B) during a subsequent remelting process, providing the received signals of parts (b) and (c) to the artificial intelligence subsystem, the machine learning subsystem, or the neural network; and (C) using the artificial intelligence subsystem, the machine learning subsystem, or the neural network, altering, maintaining, or controlling one or more operating parameters of the furnace during the subsequent remelting process.

Example 33. The method of any one of Examples 25 through 31 wherein the computer system includes an artificial intelligence subsystem, a machine learning subsystem, or a neural network, the method further comprising: (A) providing as training data to the artificial intelligence subsystem, the machine learning subsystem, or the neural network (i) the received signals of parts (b) and (c) for multiple remelting processes, and (ii) observed or measured metal quality as a function of three-dimensional position within the corresponding ingots produced by the multiple remelting processes; (B) during a subsequent remelting process, providing the received signals of parts (b) and (c) to the artificial intelligence subsystem, the machine learning subsystem, or the neural network; and (C) using the artificial intelligence subsystem, the machine learning subsystem, or the neural network, generating and storing a map of the ingot produced by the subsequent remelting process, the map indicating, as a function of longitudinal or three-dimensional position within the ingot, remelting conditions, metal quality, or specified or recommended post-melt processing.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed example embodiment. Therefore, the present disclosure shall be construed as implicitly disclosing any embodiment having any suitable subset of one or more features—which features are shown, described, or claimed in the present application—including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth, or if a differing interpretation is implicit or inherent (e.g., some small integer quantities). For null quantities described by phrases such as “equal to zero,” “absent,” “eliminated,” “negligible,” “prevented,” and so forth (with or without terms such as “about,” “substantially,” and so forth), each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled. Terms such as “parallel,” “perpendicular,” “orthogonal,” “flush,” “aligned,” and so forth shall be similarly interpreted (with or without terms such as “about,” “substantially,” and so forth).

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim.

In the appended claims, if the provisions of 35 USC § 112(f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112(f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. An apparatus comprising:
(a) first and second longitudinal electrical conductors positioned end-to-end within a current-containing volume through which a primary electric current flows in a predominantly longitudinal direction (i) through at least portions of the first and second conductors, and (ii) as one or more transversely localized electric current segments spanning a gap separating the first and second conductors, the one or more current segments being movable in two transverse dimensions within the gap;
(b) multiple magnetic field sensors (i) arranged to measure magnetic field components in one or more spatial dimensions or magnetic field magnitude, and (ii) located at corresponding sensor positions arranged about a lateral periphery of the current-containing volume at multiple different longitudinal positions and multiple different circumferential positions; and
(c) computer system comprising one or more electronic processors and one or more digital storage media coupled thereto, the computer system being structured, connected, and programmed so as to (i) receive from the magnetic field sensors corresponding signals indicative of magnetic field components measured at multiple corresponding sensor positions longitudinally offset from the gap, and (ii) based at least in part on two or more of the measured magnetic field components, calculate an estimated transverse spatial distribution of current within or through one or both of the first and second conductors.

2. The apparatus of claim 1 wherein at least one of the current segments is an electric discharge or arc formed across the gap between the first and second conductors.

3. The apparatus of claim 1, the current-containing volume being an interior volume of a remelting furnace, the first conductor being an electrode of the remelting furnace, and the second conductor being an ingot formed by a remelting process in a crucible of the remelting furnace.

4. The apparatus of claim 3 wherein at least one of the one or more current segments is an electric discharge or arc formed across the gap between the electrode and the ingot.

5. The apparatus of claim 3 wherein at least one of the current segments is a transient short circuit through a droplet of molten metal that drips across the gap between the electrode and the ingot.

6. The apparatus of claim 3 wherein a layer of molten slag at least partially fills the gap between the electrode and the ingot, and the one or more current segments pass through the slag layer.

7. The apparatus of claim 3, the computer system being structured, connected, and programmed so as to calculate, based at least in part on two or more of the measured magnetic field components, a longitudinal or transverse position of a shelf-collapse event of a solidifying portion of a melt pool at a top surface of the ingot.

8. The apparatus of claim 3 wherein the computer system is structured, connected, and programmed so as to (i) receive from the magnetic field sensors corresponding signals indicative of magnetic field components measured at multiple corresponding sensor positions, (ii) receive signals indicative of magnitude of the primary electric current and furnace voltage across the electrode and ingot, (iii) detect a drip short between the electrode and the ingot based on measured transient deviations in the primary electric current or the furnace voltage indicative of a drip short, and (iv) based at least in part on two or more of the magnetic field components measured at the time of the detected drip short, calculate an estimated transverse position of the detected drip short within the gap.

9. The apparatus of claim 1, the computer system being further structured, connected, and programmed so as to (i) receive from the magnetic field sensors corresponding signals indicative of magnetic field components measured at multiple corresponding sensor positions, (ii) based at least in part on two or more of the measured magnetic field components, calculate an estimated transverse position or distribution of the one or more current segments within the gap.

10. The apparatus of claim 1 further comprising a transverse actuator arranged so as to provide transverse or angular movement of the first or second conductors relative to one another, the computer system being further structured, connected, and programmed so as to (i) generate one or more transverse-position control signals, based at least in part on one or both of the estimated transverse position or distribution of the one or more primary electric discharges or the estimated relative transverse offset of the first and second conductors, and (ii) transmit to the transverse actuator the one or more transverse-position control signals so as to alter, maintain, or control relative transverse position or angle of the first and second conductors.

11. The apparatus of claim 1 further comprising a longitudinal actuator arranged so as to provide longitudinal movement of the first or second conductors relative to one another, the computer system being further structured, connected, and programmed so as to (i) calculate, based at least in part on two or more of the measured magnetic field components, an estimated gap distance between the first and second conductors, (ii) generate one or more longitudinal-position control signals, based at least in part on the estimated gap distance, and (ii) transmit to the longitudinal actuator the one or more longitudinal-position control signals so as to alter, maintain, or control an estimated gap distance between the first or second conductors.

12. The apparatus of claim 1 further comprising one or more magnetic field sources located at corresponding source positions arranged about the lateral periphery of the current-containing volume and arranged so as to apply a corresponding applied magnetic field having a corresponding non-zero component directed transversely across at least a portion of the current-containing volume that includes the gap, the computer system being further structured, connected, and programmed so as to (i) generate one or more applied-field control signals, based at least in part on one or both of the estimated transverse position or distribution of the one or more current segments within the gap, and (ii) transmit to the magnetic field sources the one or more applied-field control signals so as to alter, maintain, or control a position or distribution of the one or more current segments within the gap.

13. The apparatus of claim 1, the computer system being structured, connected, and programmed so as to calculate, based at least in part on two or more of the measured magnetic field components, (i) an estimated relative transverse offset or relative angle of the first and second conductors, (ii) a longitudinal shape profile of one or both of the first or second conductors, or (iii) corresponding positions, sizes, or shapes of one or more cracks, inclusions, cavities, or structural defects within one or both of the first or second conductors.

14. An apparatus comprising:
(a) a longitudinal first conductor, arranged as an electrode, and a longitudinal second conductor, arranged as an ingot, positioned end-to-end within a current-containing volume within an arc furnace through which a primary electric current flows in a predominantly longitudinal direction (i) through at least portions of the electrode and ingot, and (ii) as one or more primary electric discharges spanning a gap separating the electrode and the ingot, the one or more primary discharges being movable in two transverse dimensions within the gap;
(b) multiple magnetic field sensors (i) arranged to measure magnetic field components in two or more spatial dimensions and (ii) located at corresponding sensor positions arranged about a lateral periphery of the arc furnace at multiple different longitudinal positions and multiple different circumferential positions; and
(c) computer system comprising one or more electronic processors and one or more digital storage media coupled thereto, the computer system being structured, connected, and programmed so as to (i) receive from the magnetic field sensors corresponding signals indicative of magnetic field components measured at multiple corresponding sensor positions, (ii) receive signals indicative of magnitude of the primary electric current and furnace voltage across the electrode and ingot, (iii) detect a drip short between the electrode and the ingot based on measured transient deviations in the primary electric current or the furnace voltage indicative of a drip short, and (iv) based at least in part on two or more of the magnetic field components measured at the time of the detected drip short, calculate an estimated transverse position of the detected drip short within the gap.

15. The apparatus of claim 14, the computer system being further structured, connected, and programmed so as to calculate estimated transverse positions for multiple detected drip shorts and to calculate a transverse spatial distribution of those multiple estimated drip short positions.

16. The apparatus of claim 14, the computer system being further structured, connected, and programmed so as to (i) receive from the magnetic field sensors corresponding signals indicative of magnetic field components measured at multiple corresponding sensor positions, and (ii) based at least in part on two or more of the measured magnetic field components, calculate an estimated transverse position or distribution of the one or more primary electric discharges within the gap.

17. The apparatus of claim 14 further comprising one or more magnetic field sources located at corresponding source positions arranged about the lateral periphery of the arc furnace and arranged so as to apply a corresponding applied magnetic field having a corresponding non-zero component directed transversely across at least a portion of the arc furnace that includes the gap, the computer system being further structured, connected, and programmed so as to (i) generate one or more applied-field control signals, based at least in part on one or both of the estimated distribution of drip shorts or the estimated transverse position or distribution of the one or more primary electric discharges, and (ii) transmit to the magnetic field sources the one or more applied-field control signals so as to alter, maintain, or control a position or distribution of the one or more primary discharges which in turn alters, maintains, or controls the distribution of drip shorts.

18. An apparatus comprising:
(a) first and second longitudinal electrical conductors positioned end-to-end within a current-containing volume through which a primary electric current flows in a predominantly longitudinal direction (i) through at least portions of the first and second conductors, and (ii) as one or more transversely localized electric current segments spanning a gap separating the first and second conductors, the one or more current segments being movable in two transverse dimensions within the gap;
(b) multiple magnetic field sensors (i) arranged to measure magnetic field components in one or more spatial dimensions or magnetic field magnitude, and (ii) located at corresponding sensor positions arranged about a lateral periphery of the current-containing volume at multiple different longitudinal positions and multiple different circumferential positions; and
(c) computer system comprising one or more electronic processors and one or more digital storage media coupled thereto, the computer system being structured, connected, and programmed so as to (i) receive from the magnetic field sensors corresponding signals indicative of magnetic field components measured at multiple corresponding sensor positions, and (ii) based at least in part on two or more of the measured magnetic field components, calculate an estimated transverse spatial distribution of current segments within the gap or current within or through one or both of the first and second conductors,
(d) the current-containing volume being an interior volume of a remelting furnace, the first conductor being an electrode of the remelting furnace, and the second conductor being an ingot formed by a remelting process in a crucible of the remelting furnace,
(e) the apparatus further comprising corresponding additional sensors coupled to or positioned on or in the furnace and arranged for measuring one or more or all of (i) longitudinal or transverse position or velocity of the electrode or one or more actuators coupled to the electrode, (ii) weight of the electrode, (iii) magnitude of the operating current or fluctuations thereof, (iv) a difference between the operating current and the primary current, (v) voltage drop between the electrode and the ingot, or fluctuations thereof, (vi) electrical resistance across the gap, or fluctuations thereof, (vii) temperature within the furnace, (viii) one or more temperature gradients within or along the electrode, within or along the ingot, or along or around the crucible, (ix) pressure or composition of gas or vapor within the furnace, (x) optical spectral properties light emitted by the one or more current segments, or (xi) images of an interior of the furnace.

19. A method employing the apparatus of claim 18, the method comprising recording, as a function of longitudinal position along the ingot formed by a remelting process within the remelting furnace, one or more of: (i) transverse position or distribution of one or more current segments; (ii) transverse position or distribution of multiple drip shorts; (iii) angle or transverse position of the electrode within the crucible; (iv) distance across the gap between the electrode and the ingot; (v) a surface profile of the electrode obtained by estimating distance across the gap as a function of transverse position of the current segment; (vi) presence or duration or position of one or more side arcs; (vii) presence or duration or position of one or more constricted arcs, glows, or long arcs; (viii) detection of presence or position of a crack or defect in the electrode during a corresponding temporal portion of the remelting process that produced the ingot, (ix) longitudinal shape of the electrode, (x) gas pressure or composition within the furnace, (xi) slag depth or composition within the furnace, (xii) occurrence or position of a shelf-collapse event into the melt pool, (xiii) transient fluctuations of current or voltage or electrical resistance across the gap, (xiv) immersion depth of the electrode into molten slag filling the gap, (xv) measured magnetic field components, or (xvi) applied magnetic field components.

20. A method employing the apparatus of claim 18, the method comprising, in response to one or more magnetic field components measured by one or more corresponding sensors during a remelting process, or one or more estimated quantities calculated therefrom, performing one or more of: (i) aborting the remelting process; (ii) temporarily interrupting and then restarting the remelting process; (iii) rejecting or downgrading the ingot; (iv) rejecting or downgrading only selected portions of the ingot; (v) applying a magnetic field to alter, maintain, or control transverse position or distribution of one or more current segments within the gap; (vi) applying a magnetic field to alter, maintain, or control transverse distribution of multiple drip shorts within the gap; (vii) applying a magnetic field to alter, maintain, or control transverse distribution of heat deposited on a surface of the ingot; (viii) applying a magnetic field to attenuate or terminate a side arc, constricted arc, glow, or long arc; (ix) altering, maintaining, or controlling distance between the electrode and the ingot across the gap; (x) altering, maintaining, or controlling angle or transverse position of the electrode within the crucible; (xi) altering, maintaining, or controlling voltage across the gap; (xii) altering, maintaining, or controlling electrical resistance across the gap; (xiii) altering, maintaining, or controlling current flowing through the electrode and the ingot; (xiv) altering, maintaining, or controlling immersion depth of the electrode into molten slag filling the gap; or (xv) altering, maintaining, or controlling gas pressure or composition within the furnace.

21. A method employing the apparatus of claim 18, the method comprising:
(a) during a remelting process using the remelting furnace, delivering an operating electric current to the furnace, at least a portion of the operating electric current flowing through the furnace as the primary electric current;
(b) using the multiple magnetic field sensors, measuring magnetic field components in one or more spatial dimensions or magnetic field magnitudes at some or all of the corresponding sensor positions as a function of time during the remelting process;
(c) using the corresponding additional sensors, measuring, as a function of time during the remelting process, one or more or all of (i) longitudinal or transverse position or velocity of the electrode or one or more actuators coupled to the electrode, (ii) weight of the electrode, (iii) magnitude of the operating current or fluctuations thereof, (iv) a difference between the operating current and the primary current, (v) voltage drop between the electrode and the ingot, or fluctuations thereof, (vi) electrical resistance across the gap, or fluctuations thereof, (vii) temperature within the furnace, (viii) one or more temperature gradients within or along the electrode, within or along the ingot, or along or around the crucible, (ix) pressure or composition of gas or vapor within the furnace, (x) optical spectral properties light emitted by the one or more current segments, (xi) immersion depth of the electrode into molten slag filling the gap, or fluctuations thereof, or (xii) images of an interior of the furnace; and
(d) using the computer system (i) receiving signals indicative of some or all of the magnetic field component measured in part (b), (ii) receiving signals indicative of some or all of the quantities measured in part (c), and one or both of (iii) based at least in part on the received signals or parts (b) or (c), or on quantities or parameters calculated, estimated, or derived therefrom, altering, maintaining, or controlling one or more operating parameters of the furnace during the remelting process, or (iv) based at least in part on the received signals of parts (b) or (c), or on quantities or parameters calculated, estimated, or derived therefrom, generating and storing a longitudinal or three-dimensional map of the ingot produced by the remelting process.

22. A method comprising:
(a) during a remelting process using a remelting furnace, delivering an operating electric current to the furnace, at least a portion of the operating electric current flowing as a primary electric current in a generally longitudinal direction (i) through at least a portion of a metal electrode positioned within a crucible of the remelting furnace, (ii) through at least a portion of a metal ingot formed within the crucible by melting of the electrode during the remelting process, and (iii) as one or more transversely localized electric current segments spanning a gap separating the electrode and the ingot, the one or more current segments being movable in two transverse dimensions within the gap;
(b) using multiple magnetic field sensors located at corresponding stationary or movable sensor positions arranged about a lateral periphery of the crucible at multiple different longitudinal positions and multiple different circumferential positions, measuring magnetic field components in one or more spatial dimensions or magnetic field magnitudes at some or all of the corresponding sensor positions as a function of time during the remelting process;
(c) using corresponding sensors coupled to or positioned on or in the furnace, measuring, as a function of time during the remelting process, one or more or all of (i) longitudinal or transverse position or velocity of the electrode or one or more actuators coupled to the electrode, (ii) weight of the electrode, (iii) magnitude of the operating current or fluctuations thereof, (iv) a difference between the operating current and the primary current, (v) voltage drop between the electrode and the ingot, or fluctuations thereof, (vi) electrical resistance across the gap, or fluctuations thereof, (vii) temperature within the furnace, (viii) one or more temperature gradients within or along the electrode, within or along the ingot, or along or around the crucible, (ix) pressure or composition of gas or vapor within the furnace, (x) optical spectral properties light emitted by the one or more current segments, (xi) immersion depth of the electrode into molten slag filling the gap, or fluctuations thereof, or (xii) images of an interior of the furnace; and
(d) using a computer system that comprises one or more electronic processors and one or more digital storage media coupled thereto, and that is structured, connected, and programmed therefor, (i) receiving signals indicative of some or all of the magnetic field component measured in part (b), (ii) receiving signals indicative of some or all of the quantities measured in part (c), and one or both of (iii) based at least in part on the received signals or on quantities or parameters calculated, estimated, or derived therefrom, altering, maintaining, or controlling one or more operating parameters of the furnace during the remelting process, or (iv) based at least in part on the received signals or on quantities or parameters calculated, estimated, or derived therefrom, generating and storing a longitudinal or three-dimensional map of the ingot produced by the remelting process.

23. The method of claim 22 comprising, based at least in part on the received signals or on quantities or parameters calculated, estimated, or derived therefrom, performing during the remelting process one or more of: (i) aborting the remelting process; (ii) temporarily interrupting and then restarting the remelting process; (iii) rejecting or downgrading the ingot or only selected portions thereof; (iv) specifying or recommending specific post-melt processing of the ingot or only specific portions thereof; (v) applying a magnetic field to alter, maintain, or control transverse position or distribution of one or more current segments within the gap; (vi) applying a magnetic field to alter, maintain, or control transverse distribution of multiple drip shorts within the gap; (vii) applying a magnetic field to alter, maintain, or control transverse distribution of heat deposited on a surface of the ingot; (viii) applying a magnetic field to attenuate or terminate a side arc, constricted arc, glow, or long arc; (ix) alter, maintain, or control distance between the electrode and the ingot across the gap, or immersion depth of the electrode into molten slag filling the gap; (x) alter, maintain, or control angle or transverse position of the electrode within the crucible; (xi) alter, maintain, or control voltage across the gap; (xii) alter, maintain, or control electrical resistance across the gap; (xiii) alter, maintain, or control current flowing through the electrode and the ingot; or (xiv) alter, maintain, or control gas pressure or composition within the furnace.

24. The method of claim 22, the method comprising recording, as a function of longitudinal position along the ingot formed by a remelting process within the remelting furnace, one or more of: (i) transverse position or distribution of one or more current segments; (ii) transverse position or distribution of multiple drip shorts; (iii) angle or transverse position of the electrode within the crucible; (iv) distance across the gap between the electrode and the ingot; (v) a surface profile of the electrode obtained by estimating distance across the gap as a function of transverse position of the current segment; (vi) presence or duration or position of one or more side arcs; (vii) presence or duration or position of one or more constricted arcs, glows, or long arcs; (viii) detection of presence or position of a crack or defect in the electrode during a corresponding temporal portion of the remelting process that produced the ingot, (ix) longitudinal shape of the electrode, (x) gas pressure or composition within the furnace, (xi) slag depth or composition within the furnace, (xii) occurrence or position of a shelf-collapse event into the melt pool, (xiii) transient fluctuations of current or voltage or electrical resistance across the gap, (xiv) one or more magnetic field components; (xv) one or more applied magnetic field components, or (xvi) immersion depth of the electrode into molten slag filling the gap.

25. The method of claim 24, the map indicating, as a function of longitudinal or three-dimensional position within the ingot, remelting conditions, metal quality, or specified or recommended post-melt processing.

26. The method of claim 22 wherein the computer system includes an artificial intelligence subsystem, a machine learning subsystem, or a neural network, the method further comprising:
providing as training data to the artificial intelligence subsystem, the machine learning subsystem, or the neural network (i) the received signals of parts (b) and (c) for multiple remelting processes, and (ii) observed or measured metal quality as a function of three-dimensional position within the corresponding ingots produced by the multiple remelting processes;
during a subsequent remelting process, providing the received signals of parts (b) and (c) to the artificial intelligence subsystem, the machine learning subsystem, or the neural network; and
using the artificial intelligence subsystem, the machine learning subsystem, or the neural network, altering, maintaining, or controlling one or more operating parameters of the furnace during the subsequent remelting process.

27. The method of claim 22 wherein the computer system includes an artificial intelligence subsystem, a machine learning subsystem, or a neural network, the method further comprising:
providing as training data to the artificial intelligence subsystem, the machine learning subsystem, or the neural network (i) the received signals of parts (b) and (c) for multiple remelting processes, and (ii) observed or measured metal quality as a function of three-dimensional position within the corresponding ingots produced by the multiple remelting processes;
during a subsequent remelting process, providing the received signals of parts (b) and (c) to the artificial intelligence subsystem, the machine learning subsystem, or the neural network; and
using the artificial intelligence subsystem, the machine learning subsystem, or the neural network, generating and storing a map of the ingot produced by the subsequent remelting process, the map indicating, as a function of longitudinal or three-dimensional position within the ingot, remelting conditions, metal quality, or specified or recommended post-melt processing.
